(19) United States
(12) Patent Application Publication
(10) Pub. No.: US 2026/0123134 A1
(43) Pub. Date: Apr. 30, 2026

(54) DISPLAY PANEL, METHOD OF MANUFACTURING THE SAME, AND ELECTRONIC APPARATUS INCLUDING DISPLAY PANEL

(71) Applicant: Samsung Display Co., Ltd., Yongin-si (KR)

(72) Inventors: Seongwon Kim, Yongin-si (KR); Jonghwa Park, Yongin-si (KR); Junsu Park, Yongin-si (KR); Junhyeong Park, Yongin-si (KR); Mankyu Jo, Yongin-si (KR)

(21) Appl. No.: 19/340,799

(22) Filed: Sep. 25, 2025

(30) Foreign Application Priority Data
Oct. 25, 2024 (KR) 10-2024-0147867

(51) Int. Cl. H10H 29/39; H10H 29/01; H10H 29/49

(52) U.S. Cl. CPC H10H 29/39; H10H 29/012; H10H 29/49

(57) ABSTRACT

A display panel, a method of manufacturing the same, and an electronic apparatus including the display panel are provided. The display panel includes a base layer, a first pixel circuit layer on the base layer and including a first line and a first electrode pad, a second pixel circuit layer on the base layer and including a second line and a second electrode pad, a first light-emitting diode electrically connected to the first electrode pad, a second light-emitting diode electrically connected to the second electrode pad, and a connection line on the first surface of the base layer and electrically connecting the first line and the second line to each other, wherein an upper surface of the connection line protrudes from an upper surface of the first electrode pad and an upper surface of the second electrode pad.

### CROSS-REFERENCE TO RELATED APPLICATION

This application claims priority to and the benefit of Korean Patent Application No. 10-2024-0147867, filed on Oct. 25, 2024, in the Korean Intellectual Property Office, the entire disclosure of which is incorporated by reference herein.

### BACKGROUND

### 1. Field

One or more embodiments relate to a display panel, a method of manufacturing the same, and an electronic apparatus including the display panel.

### 2. Description of the Related Art

In general, with the development of display panels that visually display electrical signals, various display panels having excellent characteristics, such as reduced thickness, lighter weight, and low power consumption, and electronic apparatuses including the display panels have been introduced. For example, research and development have been actively conducted on display panels having various structures, such as flexible display panels that are foldable or rollable into a roll shape, and stretchable display panels, and electronic apparatuses including the display panels.

### SUMMARY

In a process of bonding a light-emitting diode to an electrode pad, damage to a display panel may occur due to over-compression. In this regard, one or more embodiments include a display panel, a process of manufacturing the display panel, and an electronic apparatus including the display panel. However, the embodiments are examples and do not limit the scope of the present disclosure.

Additional aspects will be set forth in part in the description which follows and, in part, will be apparent from the description, or may be learned by practice of embodiments of the present disclosure.

According to one or more embodiments, a display panel includes a base layer including a first surface and a second surface opposite to the first surface, a first pixel circuit layer on the first surface of the base layer and including insulating layers, a first line, and a first electrode pad, a second pixel circuit layer on the first surface of the base layer, spaced from the first pixel circuit layer, and including insulating layers, a second line, and a second electrode pad, a first light-emitting diode on the first pixel circuit layer and electrically connected to the first electrode pad, a second light-emitting diode on the second pixel circuit layer and electrically connected to the second electrode pad, and a connection line on the first surface of the base layer and electrically connecting the first line and the second line to each other, wherein each of the connection line, the first electrode pad, and the second electrode pad has a lower surface and an upper surface, the lower surface facing the base layer, and the upper surface opposite the lower surface, and the upper surface of the connection line protrudes from the upper surface of the first electrode pad and the upper surface of the second electrode pad.

In one or more embodiments, as the connection line is further away from the first light-emitting diode and the second light-emitting diode, the connection line may become thicker in a thickness direction of the display panel.

In one or more embodiments, in a plan view, as the connection line is further away from the first light-emitting diode and the second light-emitting diode, the connection line may become thicker in a direction crossing an extension direction of the connection line.

In one or more embodiments, the base layer may fill an opening defined by the first pixel circuit layer and the second pixel circuit layer.

In one or more embodiments, the connection line may fill a portion of an opening defined by the first pixel circuit layer and the second pixel circuit layer.

In one or more embodiments, a side of the opening may have a stepped shape.

In one or more embodiments, each of bonding layers may be between the first light-emitting diode or the first electrode pad and between the second light-emitting diode and the second electrode pad.

In one or more embodiments, each of the first line and the second line may include a first portion, a second portion, and a bridge line, the second portion being spaced from the first portion, and the bridge line connecting the first portion and the second portion to each other.

In one or more embodiments, the display panel may further include a cover layer on the first light-emitting diode, the second light-emitting diode, and the connection line, wherein the base layer and the cover layer may include an elastic body.

In one or more embodiments, the lower surface of the connection line may be in contact with the base layer, and the upper surface of the connection line may be in contact with the cover layer.

According to one or more embodiments, a method of manufacturing a display panel includes forming a pixel circuit layer on a first substrate, the pixel circuit layer including insulating layers, a first line, a second line, a first electrode pad electrically connected to the first line, and a second electrode pad electrically connected to the second line, forming a bonding layer overlapping each of the first electrode pad and the second electrode pad, forming a connection line that electrically connects the first line and the second line to each other, attaching a first light-emitting diode to the first electrode pad and attaching a second light-emitting diode to the second electrode pad, forming a cover layer on the first light-emitting diode, the second light-emitting diode, and the connection line, separating the first substrate and the pixel circuit layer from each other, forming an opening, a first pixel circuit layer, and a second pixel circuit layer by removing a portion of the pixel circuit layer, the first pixel circuit layer and the second pixel circuit layer being spaced from each other with the opening therebetween, and forming a base layer supporting the first pixel circuit layer and the second pixel circuit layer.

In one or more embodiments, the attaching of the first light-emitting diode to the first electrode pad and attaching of the second light-emitting diode to the second electrode pad may include preparing a second substrate, a resin layer, and the first light-emitting diode and the second light-emitting diode, the second substrate including a first surface facing the first substrate and a second surface opposite the first surface, the resin layer being on the first surface of the second substrate, and the first light-emitting diode and the second light-emitting diode being attached to the resin layer, and attaching the first light-emitting diode to the first electrode pad and attaching the second light-emitting diode to the second electrode pad by pressing the second substrate.

In one or more embodiments, when the second substrate is pressed, the connection line may be in contact with the resin layer.

In one or more embodiments, as the connection line is further away from the first light-emitting diode and the second light-emitting diode, the connection line may be thicker in a thickness direction of the display panel.

In one or more embodiments, in a plan view, as the connection line is further away from the first light-emitting diode and the second light-emitting diode, the connection line may be thicker in a direction crossing an extension direction of the connection line.

According to one or more embodiments, a method of manufacturing a display panel includes forming a pixel circuit layer on a first substrate, the pixel circuit layer including insulating layers, a first line, a second line, a first electrode pad electrically connected to the first line, and a second electrode pad electrically connected to the second line, forming an opening, a first pixel circuit layer, and a second pixel circuit layer by removing a portion of the pixel circuit layer, the first pixel circuit layer and the second pixel circuit layer being spaced from each other with the opening therebetween, patterning a bonding layer to overlap each of the first electrode pad and the second electrode pad, forming a connection line that electrically connects the first line and the second line to each other, attaching a first light-emitting diode to the first electrode pad and attaching a second light-emitting diode to the second electrode pad, forming a cover layer on the first light-emitting diode, the second light-emitting diode, and the connection line, separating the first substrate, the first pixel circuit layer, the second pixel circuit layer, and the cover layer from each other, and forming a base layer supporting the first pixel circuit layer and the second pixel circuit layer.

In one or more embodiments, the attaching of the first light-emitting diode to the first electrode pad and attaching of the second light-emitting diode to the second electrode pad may include preparing a second substrate, a resin layer, and the first light-emitting diode and the second light-emitting diode, the second substrate including a first surface facing the first substrate and a second surface opposite the first surface, the resin layer being on the first surface of the second substrate, and the first light-emitting diode and the second light-emitting diode being attached to the resin layer, and attaching the first light-emitting diode to the first electrode pad and attaching the second light-emitting diode to the second electrode pad by pressing the second substrate.

In one or more embodiments, when the second substrate is pressed, the connection line may be in contact with the resin layer.

In one or more embodiments, the connection line may fill a portion of the opening.

In one or more embodiments, as the connection line is further away from the first light-emitting diode and the second light-emitting diode, the connection line may be thicker in a thickness direction of the display panel.

According to one or more embodiments, an electronic apparatus includes a display panel, and a strain sensor including a layer, a pattern, or lines in which a measurable physical quantity changes according to stretching of the display panel, wherein the display panel includes a base layer including a first surface and a second surface opposite to the first surface, a first pixel circuit layer on the first surface of the base layer and including insulating layers, a first line, and a first electrode pad, a second pixel circuit layer on the first surface of the base layer, spaced from the first pixel circuit layer, and including insulating layers, a second line, and a second electrode pad, a first light-emitting diode on the first pixel circuit layer and electrically connected to the first electrode pad, a second light-emitting diode on the second pixel circuit layer and electrically connected to the second electrode pad, and a connection line on the first surface of the base layer and electrically connecting the first line and the second line to each other, wherein each of the connection line, the first electrode pad, and the second electrode pad has a lower surface and an upper surface, the lower surface facing the base layer, and the upper surface opposite the lower surface, and the upper surface of the connection line protrudes from the upper surface of the first electrode pad and the upper surface of the second electrode pad.

Other aspects, features, and advantages than those described above will become apparent from the following drawings, claims, and detailed description.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic perspective view of a display panel according to one or more embodiments;

FIGS. 2A and 2B are perspective views showing a state in which the display panel of FIG. 1 is stretched in a first direction;

FIG. 2C is a perspective view showing a state in which the display panel of FIG. 1 is stretched in a second direction;

FIG. 2D is a perspective view showing a state in which the display panel of FIG. 1 is stretched in the first direction and the second direction;

FIG. 2E is a perspective view showing a state in which the display panel of FIG. 1 is stretched in a third direction;

FIGS. 3A and 3B are each a schematic plan view showing an excerpt of a display area of a display panel, according to one or more embodiments;

FIG. 4 is a schematic diagram of an electronic apparatus according to one or more embodiments;

FIG. 5A-5D are equivalent circuit diagrams of a pixel of a display panel, according to one or more embodiments;

FIG. 6A-6D are each a schematic cross-sectional view of a light-emitting diode of a display panel, according to one or more embodiments;

FIG. 7 is a schematic plan view of a portion of a display area of a display panel, according to one or more embodiments;

FIG. 8 is a cross-sectional view of the display panel of FIG. 7 taken along the line I-I′ of FIG. 7;

FIG. 9A-9H are cross-sectional views showing a process based on a method of manufacturing a display panel, according to one or more embodiments;

FIG. 10 is a schematic plan view of a portion of a display area of a display panel, according to one or more embodiments;

FIG. 11 is a schematic cross-sectional view of a portion of a display panel, according to one or more embodiments;

FIG. 12 is a schematic plan view of a portion of a display area of a display panel, according to one or more embodiments;

FIG. 13A-13D are cross-sectional views showing a process based on a method of manufacturing a display panel, according to one or more embodiments;

FIG. 14 is a schematic cross-sectional view of a portion of a display panel, according to one or more embodiments;

FIG. 15A is a schematic perspective view of an electronic apparatus including a display panel, according to one or more embodiments;

FIG. 15B is a block diagram of an electronic apparatus including a display panel, according to one or more embodiments;

FIG. 16A-16D are respectively schematic perspective views showing embodiments of an electronic apparatus including a display panel, according to one or more embodiments; and

FIG. 17A-17E are respectively schematic perspective views showing embodiments of an electronic apparatus including a display panel, according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or any variations thereof.

As various modifications may be applied and numerous embodiments may be implemented, particular embodiments will be illustrated in the drawings and described in detail in the written description. Effects, aspects, and features, and methods for achieving them will be clarified with reference to embodiments described below in detail with reference to the drawings. However, embodiments may have different forms and should not be construed as being limited to the descriptions set forth herein.

Hereinafter, embodiments will now be described in detail with reference to the accompanying drawings. When described with reference to the drawings, identical or corresponding elements will be given the same reference numerals, and redundant description of these elements will be omitted.

It will be understood that although the terms “first”, “second”, etc. may be used herein to describe various elements, these elements should not be limited by these terms. These elements are only used to distinguish one element from another.

As used herein, the singular forms include the plural forms unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, a region, or an element is referred to as being “on,” another layer, region, or element, it may be directly on the other layer, region, or element, or intervening layers, regions, or elements may be present therebetween.

It will be understood that when a layer, region, or element is referred to as being “connected to” another layer, region, or element, it may be “directly connected to” the other layer, region, or element or may be “indirectly connected to” the other layer, region, or element with one or more intervening layers, regions, or elements therebetween. For example, it will be understood that when a layer, region, or element is referred to as being “electrically connected to” another layer, region, or element, it may be “directly electrically connected to” the other layer, region, or element and/or may be “indirectly electrically connected to” the other layer, region, or element with one or more intervening layers, regions, or elements therebetween.

In the present specification, the expression “A and/or B” indicates A, B, or A and B. In addition, the expression such as “at least one of A and B” may include A, B, or A and B.

In the present specification, the x-axis, the y-axis, and the z-axis are not limited to directions according to three axes of the rectangular coordinate system, and may be interpreted in a broader sense. For example, the x-axis, the y-axis, and the z-axis may be orthogonal to each other, but may refer to different directions that are not orthogonal to each other.

In the present specification, the term “plane” refers to when a target portion is viewed from above (e.g., when viewed in a direction perpendicular to the upper surface of a substrate), and the term “cross-sectional” refers to when a vertically cut cross-section of the target portion is viewed from the side.

In the present specification, when a first element overlaps a second element, it may mean that the first element is arranged over or below the second element and at least partially overlaps the second element in a plane.

In the present specification, when a certain embodiment may be implemented differently, a specific process order may also be performed differently from the described order. As an example, two processes that are successively described may be performed substantially concurrently (e.g., simultaneously) or performed in an order opposite to the order described.

Sizes of elements in the drawings may be exaggerated for convenience of description. For example, because sizes and thicknesses of elements in the drawings are arbitrarily illustrated for convenience of explanation, the following embodiments are not limited thereto.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

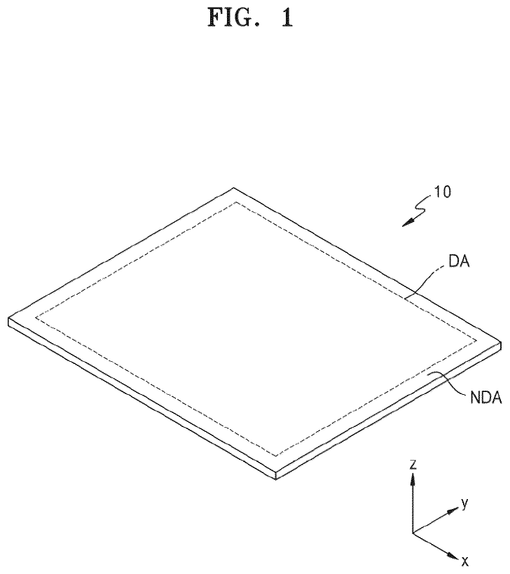

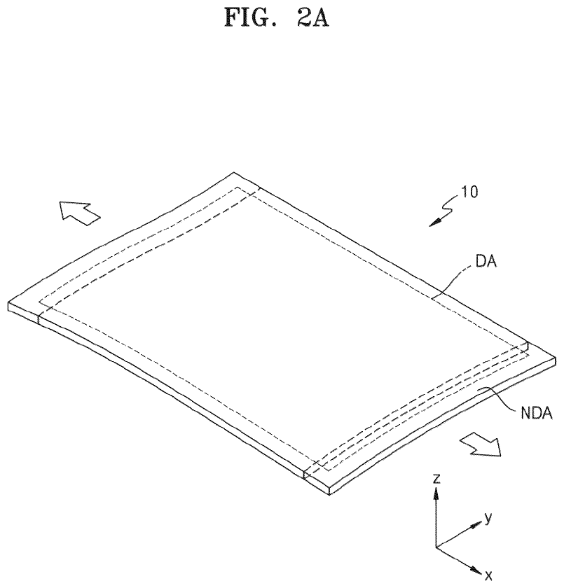

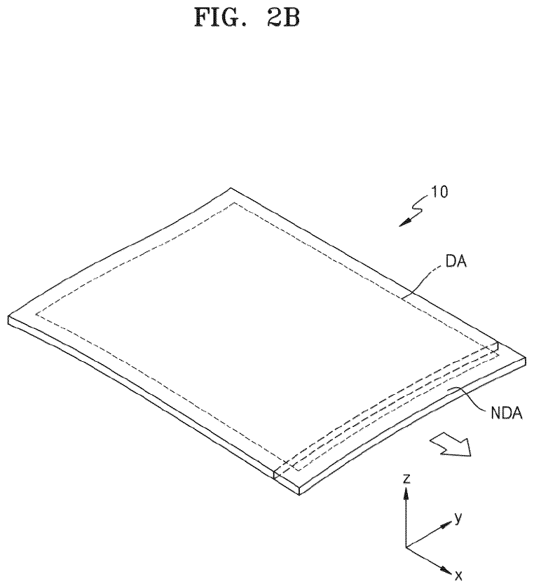

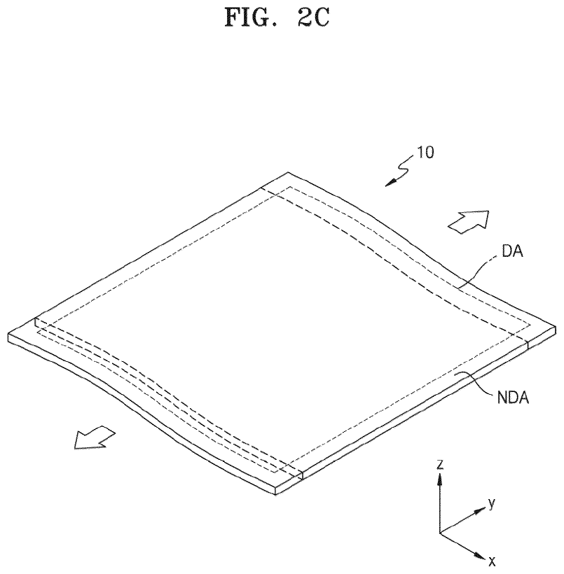

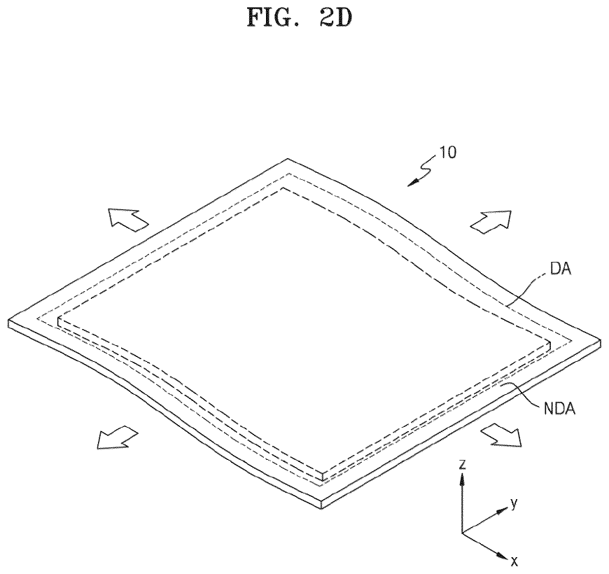

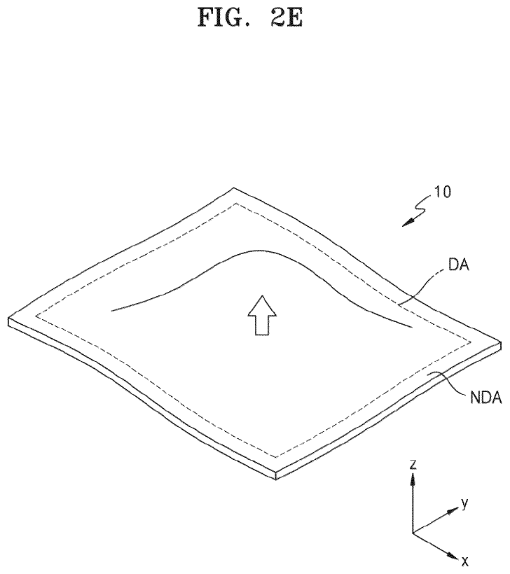

FIG. 1 is a schematic perspective view of a display panel 10 according to one or more embodiments. FIGS. 2A and 2B are perspective views showing a state in which the display panel 10 of FIG. 1 is stretched in a first direction. FIG. 2C is a perspective view showing a state in which the display panel 10 of FIG. 1 is stretched in a second direction. FIG. 2D is a perspective view showing a state in which the display panel 10 of FIG. 1 is stretched in a first direction and a second direction. FIG. 2E is a perspective view showing a state in which the display panel 10 of FIG. 1 is stretched in a third direction.

Referring to FIG. 1, the display panel 10 may include a display area DA and a non-display area NDA around an edge or a periphery of the display area DA. The display area DA may include a plurality of pixels. The display panel 10 may provide a certain image by using light emitted from the plurality of pixels. The non-display area NDA may be arranged outside the display area DA. The non-display area NDA may entirely surround the display area DA.

The display panel 10 may be stretched or contracted in various directions. The display panel 10 may be stretched in a first direction (e.g., an x-direction and/or a −x direction) by an external force applied by an external object or a user. In one or more embodiments, as shown in FIGS. 2A and 2B, the display area DA and/or the non-display area NDA of the display panel 10 may be stretched in the first direction (e.g., the x-direction and/or the −x direction). For example, as shown in FIG. 2A, the display area DA and/or the non-display area NDA of the display panel 10 may be stretched in the x-direction and the −x direction, or as shown in FIG. 2B, while one side of the display panel is fixed, the display area DA and/or the non-display area NDA of the display panel 10 may be stretched in the x-direction.

The display panel 10 may be stretched in a second direction (e.g., a y-direction and/or a −y direction) by an external force applied by an external object or a user. In one or more embodiments, as shown in FIG. 2C, the display area DA and/or the non-display area NDA of the display panel 10 may be stretched in the y-direction and the −y direction. In another embodiment, while one side of the display panel 10 is fixed, the display area DA and/or the non-display area NDA of the display panel 10 may be stretched in the y-direction or the −y direction.

The display panel 10 may be stretched in a plurality of directions, for example, in the first direction (e.g., the x-direction and/or the −x direction) and the second direction (e.g., the y-direction and/or the −y direction), by an external force applied by an external object or a part of the body of a user. As shown in FIG. 2D, the display area DA and/or the non-display area NDA of the display panel 10 may be stretched in a ±x direction and a ±y direction.

The display panel 10 may be stretched in a third direction (e.g., a z-direction or a −z direction) by an external force applied by an external object or a part of the body of a user. In one or more embodiments, FIG. 2E illustrates that a portion of the display panel 10, for example, an area of the display area DA, protrudes in the z-direction (e.g., a thickness direction). In another embodiment, a portion of the display panel 10, for example, an area of the display area DA, may protrude in the z-direction (or be recessed in the −z-direction).

FIG. 2A-2E illustrate that the display panel 10 is stretched in the first direction, the second direction, and/or the third direction, but the present disclosure is not limited thereto. In another embodiment, the display panel 10 may be transformed into various irregular shapes, such as being bent or twisted along two or more axes.

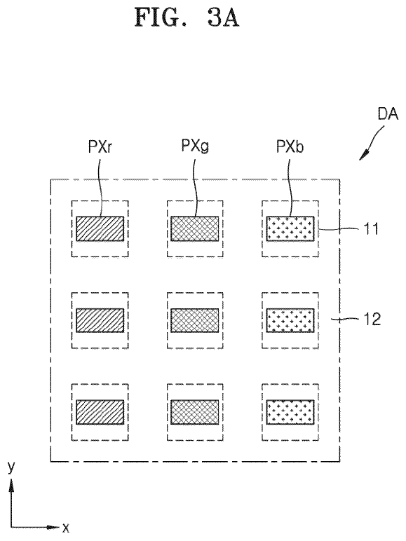

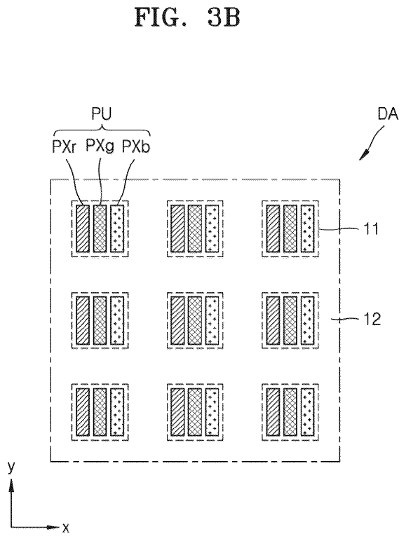

FIGS. 3A and 3B are each a schematic plan view showing an excerpt of a display area DA of a display panel, according to one or more embodiments.

Referring to FIGS. 3A and 3B, the display area DA may include first areas 11, and a second area 12 around (e.g., surrounding) each of the first areas 11. The first areas 11 may be repeatedly arranged along the first direction (e.g., the x-direction) and the second direction (e.g., the y-direction).

The display area DA may include a first area 11 and a second area 12 having different elongations. For example, the display panel 10 may include a first area 11 having a relatively small elongation and a second area 12 having a relatively large elongation. In the present specification, an elongation refers to a numerical value representing a change in length (ΔL/L) by which the display panel 10 may be stretched without physical damage to the display panel 10 when an external force is applied to the display panel 10. In this case, ΔL refers to a change in the length of an elongated area, and L refers to an initial length of the elongated area. Accordingly, the elongation of each of the first area 11 and the second area 12 may refer to a change in the length of each of the first area 11 and the second area 12 when the same external force is applied to the first area 11 and the second area 12.

When the elongation of the first area 11 is smaller than the elongation of the second area 12, it may indicate that transformation of the first area 11 caused by the external force occurs relatively less. Accordingly, the first area 11 may be referred to as a low transformation area, and the second area 12 may be referred to as a main transformation area or a high transformation area.

The first areas 11 may be spaced (e.g., spaced apart) from each other and may be two-dimensionally arranged in the display area DA. The first area 11 may be an area in which pixels are arranged, and thus, the first area 11 may be referred to as a pixel area or an emission area. One or more pixels may be arranged in each first area 11. In the present specification, one pixel refers to a sub-pixel that emits red, green, blue, or white light.

Referring to FIG. 3A, one pixel may be arranged in one first area 11. For example, a red pixel PXr, a green pixel PXg, or a blue pixel PXb may be arranged in each first area 11. Referring to FIG. 3B, a pixel unit PU including a collection of pixels may be provided in the first area 11. In one or more embodiments, each pixel unit PU may include a red pixel PXr, a green pixel PXg, and a blue pixel PXb. The red pixel PXr may include a red light-emitting diode that emits red light, the green pixel PXg may include a green light-emitting diode that emits green light, and the blue pixel PXb may include a blue light-emitting diode that emits blue light.

The elongation of the first area 11 may be relatively smaller than the elongation of the second area 12 due to light-emitting diodes arranged in the first area 11, electrode pads connected to the light-emitting diodes, and lines.

The second area 12 may be between adjacent first areas 11. The second area 12 may be referred to as a connection portion that connects the plurality of first areas 11 to each other. As shown in FIGS. 3A and 3B, in a plan view, the second area 12 may have a shape surrounding each first area 11. The second area 12 may be an area in which a connection line is arranged, the connection line electrically connecting lines in each of two adjacent first areas 11.

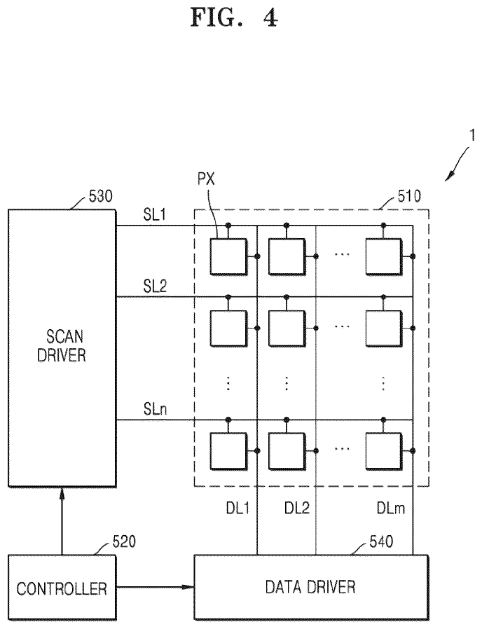

FIG. 4 is a schematic diagram of an electronic apparatus 1 according to one or more embodiments.

Referring to FIG. 4, the electronic apparatus 1 may include a display portion 510, a controller 520, a scan driver 530, and a data driver 540. In the present specification, the display portion 510 is a portion of the display panel 10 where an image is displayed, and may include a plurality of pixels PX. The display portion 510 may be provided in the display area DA of the display panel 10, and the controller 520, the scan driver 530, and the data driver 540 may be provided in the non-display area NDA.

A plurality of scan lines SL1 to SLn, a plurality of data lines DL1 to DLm, and the plurality of pixels PX connected to the scan lines SL1 to SLn and the data lines DL1 to DLm may be arranged in the display portion 510. Each pixel PX refers to a sub-pixel. Each pixel PX may be connected to a corresponding scan line from among the plurality of scan lines SL1 to SLn and a corresponding data line from among the plurality of data lines DL1 to DLm.

Each of the data lines DL1 to DLm may be connected to the pixels PX arranged in the same column. Each of the scan lines SL1 to SLn may be connected to the pixels PX arranged in the same row. When scan signals are supplied from the scan lines SL1 to SLn, the pixels PX may selectively emit light in response to data signals supplied from the data lines DL1 to DLm.

The controller 520 may generate control signals based on signals input from the outside and may supply the control signals to the scan driver 530 and the data driver 540. The scan driver 530 may be connected to the plurality of scan lines SL1 to SLn. The scan driver 530 may generate scan signals in response to the control signals from the controller 520 and sequentially supply the scan signals to the scan lines SL1 to SLn, respectively. The data driver 540 may be connected to the plurality of data lines DL1 to DLm. In response to the control signals from the controller 520, the data driver 540 may convert image data into data signals and supply the data signals to the data lines DL1 to DLm, respectively, the image data having grayscale input from the controller 520. The data signals may be input to the pixels PX in rows selected by the scan signals.

In one or more embodiments, when the display panel 10 has an active matrix structure, the display portion 510 may further receive a first power voltage and a second power voltage in addition to the scan signals and the data signals.

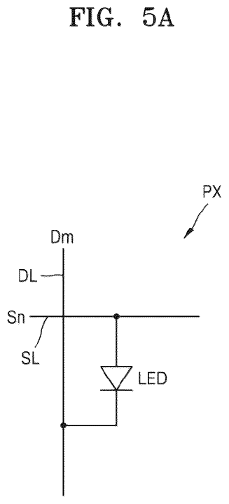

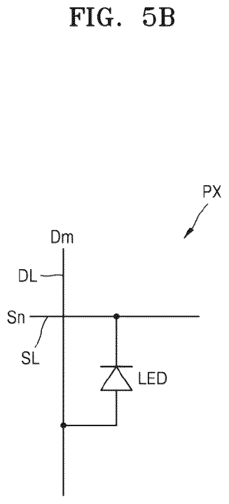

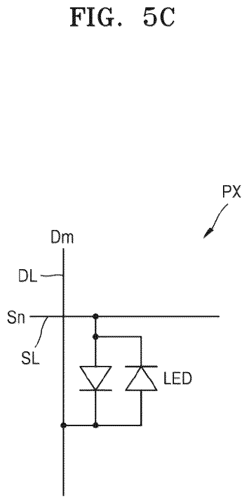

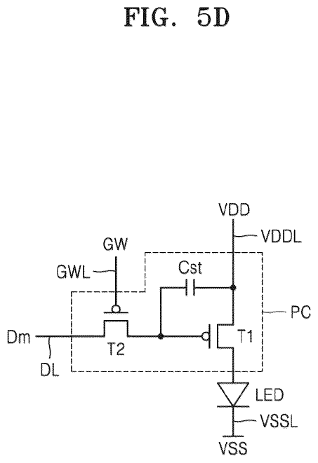

FIG. 5A-5D are equivalent circuit diagrams of a pixel PX of a display panel, according to one or more embodiments.

FIG. 5A-5C are schematic equivalent circuit diagrams of one pixel PX of the display panel 10 having a passive matrix structure, and FIG. 5D is a schematic equivalent circuit diagram of one pixel PX of the display panel 10 having an active matrix structure.

Referring to FIG. 5A, one pixel PX may include a light-emitting diode LED. A first electrode (e.g., an anode electrode) of the light-emitting diode LED may be electrically connected to a scan line SL, and a second electrode (e.g., a cathode electrode) thereof may be electrically connected to a data line DL. In one or more embodiments, a scan signal Sn applied to the scan line SL and a data signal Dm applied to the data line DL may have a negative voltage, and the other thereof may have a positive voltage. When a voltage corresponding to a threshold voltage or higher is applied between the first electrode and the second electrode, the light-emitting diode LED emits light with a brightness corresponding to the magnitude of the applied voltage.

Referring to FIG. 5B, a connection direction of the light-emitting diode LED may be changed. For example, the second electrode (e.g., a cathode electrode) of the light-emitting diode LED may be electrically connected to the scan line SL, and the first electrode (e.g., an anode electrode) thereof may be electrically connected to the data line DL. In this case, the direction of a voltage applied between the scan line SL and the data line DL may be opposite to each other.

Referring to FIG. 5C, one pixel PX may include two or more light-emitting diodes LED connected in different directions. For example, the pixel PX may include one light-emitting diode LED of which a first electrode is connected to the scan line SL and a second electrode is connected to the data line DL, and another light-emitting diode LED of which a second electrode is connected to the scan line SL and a first electrode is connected to the data line DL. In one or more embodiments, the polarity of the scan signal Sn applied to the scan line SL and the polarity of the data signal Dm applied to the data line DL may change over time. According to the direction of a voltage applied between the first electrode and the second electrode of each of the light-emitting diodes LED, a forward-connected light-emitting diode LED may emit light and a reverse-connected light-emitting diode LED may not emit light, or the forward-connected light-emitting diode LED may not emit light and the reverse-connected light-emitting diode LED may emit light. Accordingly, two light-emitting diodes LED may alternately emit light according to the scan signal Sn and the data signal Dm.

Referring to FIG. 5D, one pixel PX may include a light-emitting diode LED and a pixel circuit PC electrically connected to the light-emitting diode LED. The pixel circuit PC may include a first transistor T1, a second transistor T2, and a storage capacitor Cst. The pixel circuit PC may be electrically connected to a signal line and a voltage line. The signal line may include a gate line GWL and the data line DL, and the voltage line may include a first voltage line VDDL and a second voltage line VSSL.

The second transistor T2 may be electrically connected to the gate line GWL and the data line DL. The gate line GWL may be configured to provide a gate signal GW to a gate electrode of the second transistor T2. The second transistor T2 may be configured to transmit, to the first transistor T1, a data signal Dm input through the data line DL according to the gate signal GW input through the gate line GWL. The gate line GWL may correspond to the scan line SL of FIG. 5A, and the gate signal GW may correspond to the scan signal Sn.

The storage capacitor Cst may be electrically connected to the second transistor T2 and the first voltage line VDDL and may store a voltage corresponding to a difference between a voltage received from the second transistor T2 and a first power voltage VDD supplied through the first voltage line VDDL.

The first transistor T1 is a driving transistor and may be configured to control a driving current flowing through the light-emitting diode LED. The first transistor T1 may be connected to the first voltage line VDDL and the storage capacitor Cst. The first transistor T1 may be configured to control a driving current flowing from the first voltage line VDDL to the light-emitting diode LED in response to a voltage value stored in the storage capacitor Cst. The light-emitting diode LED may emit light having a certain luminance according to the driving current. The first electrode of the light-emitting diode LED may be electrically connected to the first transistor T1, and the second electrode thereof may be electrically connected to the second voltage line VSSL configured to supply a second power voltage VSS.

FIG. 5D illustrates that the pixel circuit PC includes two transistors and one storage capacitor, but in another embodiment, the pixel circuit PC may include three or more transistors.

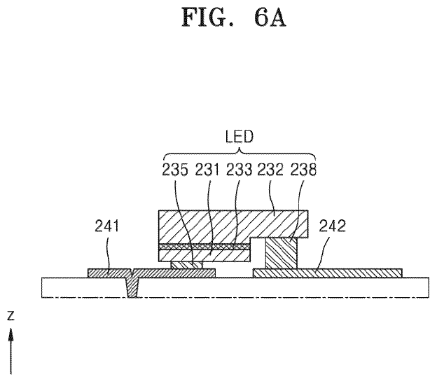

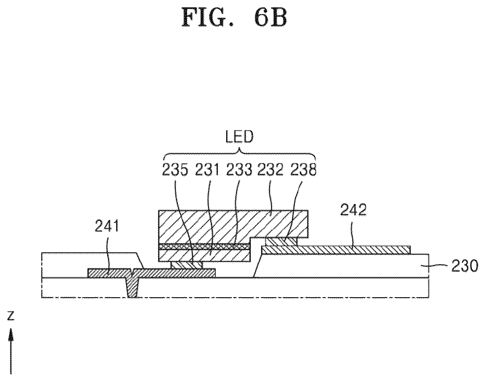

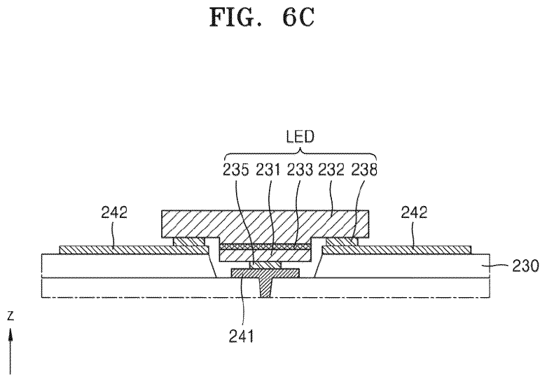

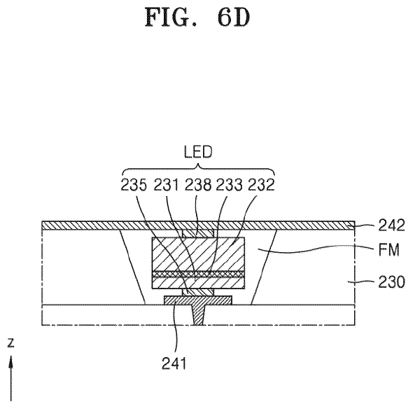

FIG. 6A-6D are each a schematic cross-sectional view of a light-emitting diode LED of a display panel, according to one or more embodiments.

Referring to FIG. 6A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 242 arranged on (or at) the same layer, respectively.

In one or more embodiments, the first semiconductor layer 231 may include a p-type semiconductor layer. The p-type semiconductor layer may be selected from among semiconductor materials with a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, etc. and may be doped with a p-type dopant such as magnesium (Mg), zinc (Zn), calcium (Ca), strontium (Sr), and/or barium (Ba).

The second semiconductor layer 232 may include, for example, an n-type semiconductor layer. The n-type semiconductor layer may be selected from among semiconductor materials with a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, etc. and may be doped with a p-type dopant such as silicon (Si), germanium (Ge), or tin (Sn).

The intermediate layer 233 may be an area where electrons and holes recombine, and as the electrons and the holes recombine, the intermediate layer 233 may transition to a lower energy level and generate light having a corresponding wavelength. The intermediate layer 233 may include a semiconductor material with a composition formula of InₓAl_{y}Ga_{1-x-y}N (0≤x≤1, 0≤y≤1, 0≤x+y≤1) and may be formed as a single quantum well structure or a multi-quantum well (MQW) structure. Also, the intermediate layer 233 may include a quantum wire structure or a quantum dot structure.

FIG. 6A illustrates that the first semiconductor layer 231 includes a p-type semiconductor layer and the second semiconductor layer 232 includes an n-type semiconductor layer, but the present disclosure is not limited thereto. In another embodiment, the first semiconductor layer 231 may include an n-type semiconductor layer, and the second semiconductor layer 232 may include a p-type semiconductor layer.

FIG. 6A illustrates that the first electrode pad 241 and the second electrode pad 242 are arranged on (or at) the same layer, but the present disclosure is not limited thereto. Referring to FIG. 6B, the first electrode pad 241 and the second electrode pad 242 may be arranged on different layers. For example, a bank layer 230 may be arranged on the first electrode pad 241, the bank layer 230 having an opening that overlaps at least a portion of the first electrode pad 241, and the second electrode pad 242 may be arranged on the upper surface of the bank layer 230. The structure of the light-emitting diode LED shown in FIG. 6B is the same as that described above with reference to FIG. 6A.

In another embodiment, as shown in FIG. 6C, the second electrode pad 242 may be arranged on both sides of the first electrode pad 241 in the cross-sectional view. The bank layer 230 may include an opening that overlaps at least a portion of the first electrode pad 241, and the second electrode pad 242 may be arranged around the opening of the bank layer 230. In one or more embodiments, in a plan view, the second electrode pad 242 may have a closed loop shape that entirely surrounds the opening of the bank layer 230 and/or the first electrode pad 241. The structure of the light-emitting diode LED shown in FIG. 6C is the same as that described above with reference to FIG. 6A.

FIG. 6A-6C illustrate that the first electrode 235 and the second electrode 238 of the light-emitting diode LED are directed in the same direction (e.g., a downward direction or a −z direction), but the present disclosure is not limited thereto. As shown in FIG. 6D, the first electrode 235 and the second electrode 238 of the light-emitting diode LED may be directed in opposite directions.

The bank layer 230 may include an opening that exposes at least a portion of the first electrode pad 241, and the thickness of the bank layer 230 and the thickness of the light-emitting diode LED may be substantially the same. The opening of the bank layer 230 may be filled with a filling material FM, and the second electrode pad 242 may be arranged on the upper surface of the bank layer 230 to be electrically connected to (e.g., in contact with) the second electrode 238 of the light-emitting diode LED. The filling material FM may include an organic material having insulating properties.

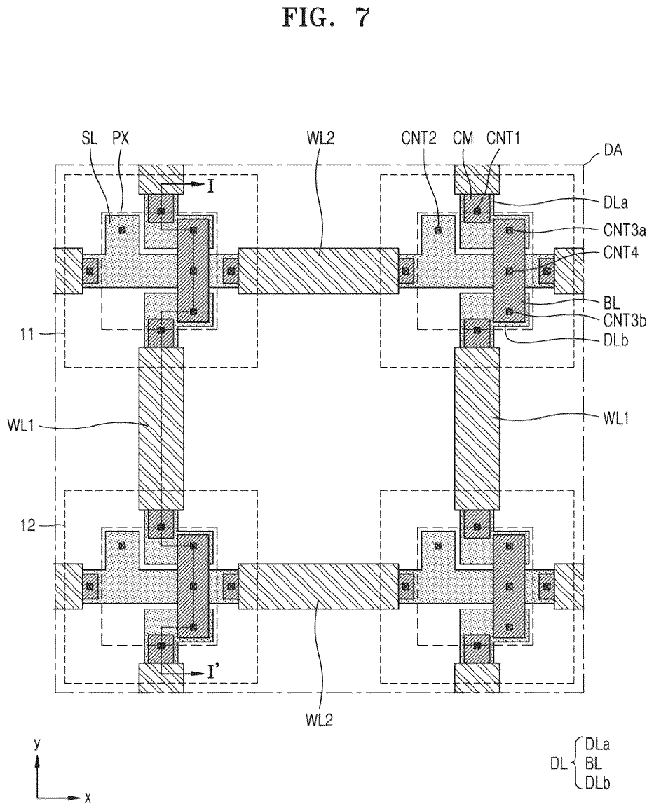

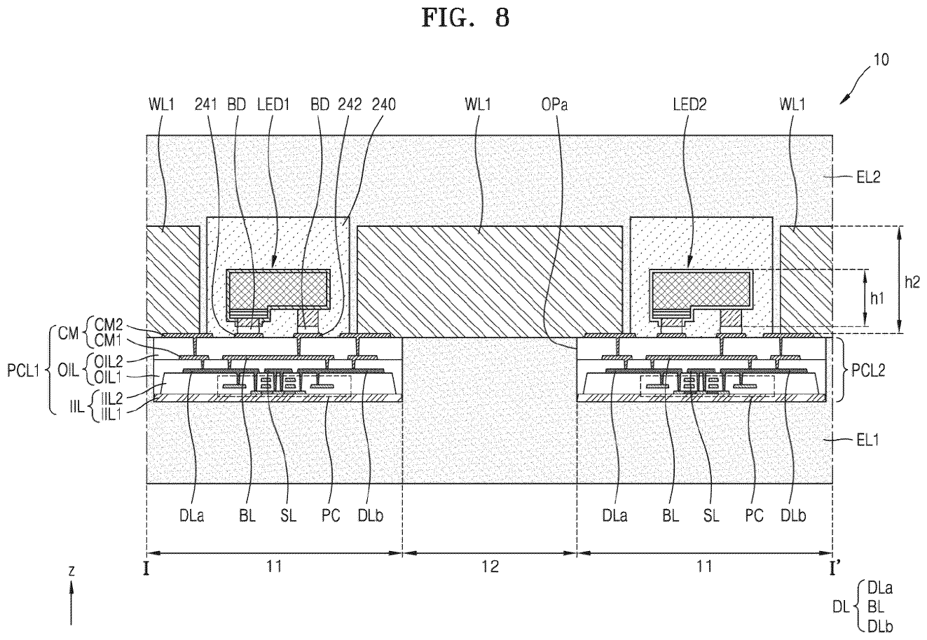

FIG. 7 is a schematic plan view of a portion of a display area of a display panel, according to one or more embodiments, and FIG. 8 is a cross-sectional view of the display panel of FIG. 7 taken along the line I-I′ of FIG. 7.

Referring to FIG. 7, the pixel PX may be arranged in the first area 11. In this regard, FIG. 7 illustrates that one pixel PX is arranged in one first area 11. Each pixel PX may include the light-emitting diode LED. The light-emitting diode LED may include an inorganic light-emitting diode. In one or more embodiments, the display 10 (see FIG. 1) may have an active matrix structure, and each pixel PX may include the pixel circuit PC (see FIG. 5D) electrically connected to the light-emitting diode LED. As described above with reference to FIG. 5D, the pixel circuit PC may include transistors and capacitors. Hereinafter, a case where the display panel 10 has an active matrix structure and each pixel PX includes the pixel circuit PC is mainly described.

The first area 11 may have a smaller elongation than that of the second area 12. Accordingly, when the display panel 10 is stretched, the first area 11 may be less transformed than the second area 12. As described above, the first area 11 may be referred to as a low transformation area (or low transformation portion). Also, the first area 11 is an area in which the light-emitting diode LED and the pixel circuit PC are arranged, and may be referred to as a pixel area or an emission area.

The second area 12 may surround the first area 11 and have a larger elongation than that of the first area 11. The second area 12 may be an area where main transformation occurs according to the stretching of a display apparatus. The second area 12 is between the plurality of first areas 11 and may be referred to as a connection portion that connects the first areas 11 to each other. Also, the second area 12 may be referred to as a main transformation area (or main transformation portion) or a high transformation area (or high transformation portion). The second area 12 is an area of the display area where no light-emitting diode is arranged, and may be referred to as a non-pixel area or a non-emission area.

Signal lines and/or voltage lines may be arranged in the display area DA. In one or more embodiments, FIG. 7 illustrates that the scan line SL and the data line DL are each arranged in the first area 11. In one or more embodiments, the scan line SL may be electrically connected to a gate electrode of a transistor included in the pixel circuit PC via a second contact hole CNT2. The data line DL may be electrically connected to one terminal of the transistor included in the pixel circuit PC via a fourth contact hole CNT4. In another embodiment, the scan line SL may be electrically connected to the first electrode pad 241 (see FIG. 6A) via the second contact hole CNT2, and the data line DL may be electrically connected to the second electrode pad 242 (see FIG. 6B) via the fourth contact hole CNT4.

Two data lines DL respectively arranged in two first areas 11 adjacent in a second direction (e.g., a y-direction) may be electrically connected to each other by a connection line (hereinafter referred to as a first connection line WL1). The first connection line WL1 may be arranged in the second area 12 and extend in the second direction (e.g., the y-direction). The first connection line WL1 may be connected to the data lines DL via contact electrodes CM and first contact holes CNT1.

Scan lines SL respectively arranged in two first areas 11 adjacent in a first direction (e.g., an x-direction) may be electrically connected to each other by a connection line (hereinafter referred to as a second connection line WL2). The second connection line WL2 may be arranged in the second area 12 and extend in the first direction (e.g., the x-direction). The second connection line WL2 may be connected to the scan lines SL via the contact electrodes CM and the first contact holes CNT1.

In other words, the scan lines SL connected to the pixels PX arranged in the same row may be electrically connected to each other by second connection lines WL2. The data lines DL connected to the pixels PX arranged in the same column may be electrically connected to each other by first connection lines WL1.

The scan line SL and the data line DL may cross each other in the first area 11. In one or more embodiments, the data line DL may include a first portion DLa and a second portion DLb separated from each other with the scan line SL therebetween, and a bridge line BL that electrically connects the first portion DLa and the second portion DLb to each other. The bridge line BL may be arranged in an area where the data line DL and the scan line SL cross each other, and may be arranged on a different layer from the scan line SL. In one or more embodiments, the first portion DLa and the second portion DLb of the data line DL and the scan line SL may be arranged on (or at) the same layer, one end of the bridge line BL may be connected to the first portion DLa via a third-1 contact hole CNT3a, and the other end of the bridge line BL may be connected to the second portion DLb via a third-2 contact hole CNT3b.

FIG. 7 illustrates that the data line DL is connected via the first portion DLa, the second portion DLb, and the bridge line BL, but the present disclosure is not limited thereto. In another embodiment, the scan line SL may be divided into a first portion and a second portion, and the first portion and the second portion may be connected to each other via a bridge line.

An elongation of each of the first connection line WL1 and the second connection line WL2 arranged in the second area 12 may be larger than an elongation of each of the scan line SL and the data line DL.

Each of the scan line SL and the data line DL may include one or more materials selected from among aluminum (Al), platinum (Pt), palladium (Pd), silver (Ag), Mg, gold (Au), nickel (Ni), neodymium (Nd), iridium (Ir), chromium (Cr), lithium (Li), Ca, molybdenum (Mo), titanium (Ti), tungsten (W), and/or copper (Cu). Each of the scan line SL and the data line DL may include a single layer or a plurality of layers including the aforementioned metal. In one or more embodiments, each of the scan line SL and the data line DL may include a metal thin film formed of a triple layer having a structure of Ti/Al/Ti.

The first connection line WL1 and the second connection line WL2 may include a liquid metal, may include a conductive composite material including a metal nanostructure, an elastic polymer, and/or an elastomer, or may include a conductive polymer. Accordingly, when the display panel 10 (see FIG. 1) is stretched, the second area 12 may be transformed relatively more than the first area 11.

FIG. 7 illustrates that the first connection line WL1 and the second connection line WL2 are straight lines in a plan view, but the present disclosure is not limited thereto. In one or more embodiments, each of the first connection line WL1 and the second connection line WL2 may have a meandering shape in a plan view.

FIG. 7 illustrates that each of the scan line SL and the data line DL is electrically connected to the second connection line WL2 and the first connection line WL1, but the present disclosure is not limited thereto. The first voltage line VDDL or the second voltage line VSSL described above with reference to FIG. 5D may be further arranged in the first area 11 and electrically connected to additional connection lines arranged in the second area 12.

Referring to FIG. 8, the display panel 10 may include a first pixel circuit layer PCL1 and a second pixel circuit layer PCL2 respectively arranged in two adjacent first areas 11, a first light-emitting diode LED1 on the first pixel circuit layer PCL1, a second light-emitting diode LED2 on the second pixel circuit layer PCL2, and the first connection line WL1 that electrically connects the data lines DL of the first pixel circuit layer PCL1 and the second pixel circuit layer PCL2 to each other.

FIG. 8 schematically illustrates the display panel 10 including an active matrix structure in which each of the first pixel circuit layer PCL1 and the second pixel circuit layer PCL2 includes the pixel circuit PC, and the pixel circuit PC includes transistors and a capacitor, but the present disclosure is not limited thereto. In one or more embodiments, the display panel 10 may have a passive matrix structure, and some of transistors and capacitors may be omitted. In the present specification, a case where the display panel 10 has an active matrix structure is mainly described below.

A base layer EL1 may include an elastic polymer. For example, the base layer EL1 may include thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and/or ecoflex.

The base layer EL1 may have a first surface (e.g., an upper surface or a surface in a +z direction) and a second surface (e.g., a lower surface or a surface in a −z direction), and the first pixel circuit layer PCL1 and the second pixel circuit layer PCL2 may be arranged over the first surface of the base layer EL1. The first pixel circuit layer PCL1 and the second pixel circuit layer PCL2 may be spaced (e.g., spaced apart) from each other in a plan view.

Each of the first pixel circuit layer PCL1 and the second pixel circuit layer PCL2 may include inorganic insulating layers IIL, organic insulating layers OIL, the pixel circuit PC, lines DL and SL, electrode pads 241 and 242, and connection electrodes CM. Each of the first pixel circuit layer PCL1 and the second pixel circuit layer PCL2 may be arranged over the first surface (e.g., the surface in the +z direction) of the base layer EL1.

The inorganic insulating layers IIL may include a first inorganic insulating layer IIL1 arranged below the pixel circuit PC, and second inorganic insulating layers IIL2 between semiconductor layers and conductive layers that constitute the pixel circuit PC. The organic insulating layers OIL may include a first organic insulating layer OIL1 arranged on the inorganic insulating layers IIL, and a second organic insulating layer OIL2 arranged on the first organic insulating layer OIL1.

The first pixel circuit layer PCL1 and the second pixel circuit layer PCL2 may be spaced (e.g., spaced) apart from each other in a plan view. As shown in FIG. 8, each of the first pixel circuit layer PCL1 and the second pixel circuit layer PCL2 may be arranged in the first area 11 and have an isolated shape. The first pixel circuit layer PCL1 and the second pixel circuit layer PCL2 may be spaced (e.g., spaced apart) from each other with an opening OPa therebetween, the opening OPa being defined by the inorganic insulating layers IIL and the organic insulating layers OIL. The opening OPa may be formed by overlapping an opening of the first inorganic insulating layer IIL1, an opening of a second inorganic insulating layer IIL2, an opening of the first organic insulating layer OIL1, and an opening of the second organic insulating layer OIL2. The opening OPa may be arranged in the second area 12 and surround the first pixel circuit layer PCL1 and the second pixel circuit layer PCL2. In one or more embodiments, the opening OPa may be filled by the base layer EL1.

In each of the first pixel circuit layer PCL1 and the second pixel circuit layer PCL2, the first inorganic insulating layer IIL1 may be arranged on the base layer EL1, and the pixel circuit PC may be arranged on the first inorganic insulating layer IIL1. The first inorganic insulating layer IIL1 may include an inorganic insulating material such as silicon oxide, silicon nitride, and/or silicon oxynitride.

The pixel circuit PC may include transistors and capacitors. The pixel circuit PC may include at least one semiconductor layer and conductive layers between the first and second inorganic insulating layers IIL1 and IIL2. The semiconductor layer may include an oxide-based semiconductor material, a silicon-based semiconductor material, and/or an organic semiconductor material. The conductive layers may include a conductive material including Mo, Al, Cu, Ti, and/or the like, and may include a multilayer or a single layer including the aforementioned conductive material.

The scan line SL and the first portion DLa and the second portion DLb of the data line DL may be arranged on the second inorganic insulating layer IIL2. Each of the scan line SL and the first portion DLa and the second portion DLb of the data line DL may include a conductive material including Mo, Al, Cu, Ti, and/or the like, and may include a multilayer or a single layer including the aforementioned conductive material. For example, the scan line SL and the first portion DLa and the second portion DLb of the data line DL may include a triple layer having a structure of Ti/Al/Ti.

The first organic insulating layer OIL1 may be arranged on the scan line SL and the first portion DLa and the second portion DLb of the data line DL. The first organic insulating layer OIL1 may include an organic insulating material. The organic insulating material may include an acrylic resin, an epoxy-based resin, polyimide, and/or polyethylene. The first organic insulating layer OIL1 may cover side surfaces of the inorganic insulating layers IIL.

The bridge line BL and first contact electrodes CM1 may be arranged on the first organic insulating layer OIL1. Each of the first contact electrodes CM1 may be electrically connected to one of the first portion DLa and the second portion DLb of the data line DL via a contact hole passing through the first organic insulating layer OIL1. One end of the bridge line BL may be electrically connected to the first portion DLa of the data line DL via a contact hole passing through the first organic insulating layer OIL1, and the other end of the bridge line BL may be electrically connected to the second portion DLb of the data line DL via a contact hole passing through the first organic insulating layer OIL1. The bridge line BL and the first contact electrodes CM1 may include a conductive material including Mo, Al, Cu, Ti, and/or the like, and may include a multilayer or a single layer including the aforementioned conductive material. For example, the bridge line BL and the first contact electrodes CM1 may include a triple layer having a structure of Ti/Al/Ti.

The second organic insulating layer OIL2 may be arranged on the bridge line BL and the first contact electrodes CM1. The second organic insulating layer OIL2 may include an organic insulating material.

The first electrode pad 241, the second electrode pad 242, and second contact electrodes CM2 may be arranged on the second organic insulating layer OIL2. The first electrode pad 241, the second electrode pad 242, and the second contact electrodes CM2 may include a conductive material including Mo, Al, Cu, Ti, and/or the like, and may include a multilayer or a single layer including the aforementioned conductive material. For example, the first electrode pad 241, the second electrode pad 242, and the second contact electrodes CM2 may include a triple layer having a structure of Ti/Al/Ti. Each of the second contact electrodes CM2 may be connected to a first contact electrode CM1 via a contact hole passing through the second organic insulating layer OIL2.

The first connection line WL1 may be arranged over the first surface (e.g., the surface in the +z direction) of the base layer EL1. The first connection line WL1 may be arranged in the second area 12 and electrically connected to a second contact electrode CM2 of the first pixel circuit layer PCL1 and a second contact electrode CM2 of the second pixel circuit layer PCL2. The first connection line WL1 may electrically connect two data lines DL (e.g., a first line and a second line) to each other via the contact electrodes CM, the data lines DL being respectively arranged in two adjacent first areas 11. One end of the first connection line WL1 may be in contact with the second contact electrode CM2 of the first pixel circuit layer PCL1, and the other end of the first connection line WL1 may be in contact with the second contact electrode CM2 of the second pixel circuit layer PCL2.

The first electrode pad 241 and the second electrode pad 242 may be electrically connected to transistors of the pixel circuit PC therebelow via connection electrodes between the first organic insulating layer OIL1 and the second organic insulating layer OIL2.

The first light-emitting diode LED1 may be arranged over the first pixel circuit layer PCL1, and the second light-emitting diode LED2 may be arranged over the second pixel circuit layer PCL2. The first light-emitting diode LED1 may be electrically connected to the first electrode pad 241 and the second electrode pad 242 of the first pixel circuit layer PCL1, and the second light-emitting diode LED2 may be electrically connected to the first electrode pad 241 and the second electrode pad 242 of the second pixel circuit layer PCL2. Each of the first light-emitting diode LED1 and the second light-emitting diode LED2 may have a structure identical or similar to that of the light-emitting diode LED described above with reference to FIG. 6A. In another embodiment, the light-emitting diode LED may have a structure as in FIG. 6B-6D.

Bonding layers BD may be between the first and second electrode pads 241 and 242 and the first and second light-emitting diodes LED1 and LED2. The bonding layers BD may be patterned in response to the first and second electrode pads 241 and 242. Each of the bonding layers BD may include Cu, indium (In), Au, Sn, and/or any alloys thereof. In one or more embodiments, each of the bonding layers BD may include a conductive composite material including a conductive particle, a metal nanostructure, and/or an elastomer.

Each of the first light-emitting diode LED1 and the second light-emitting diode LED2 may be covered with a protective layer 240. The protective layer 240 may include an organic insulating material having relatively high hardness so that the first and second light-emitting diodes LED1 and LED2 are fixed to lower layers. The protective layer 240 may reduce mechanical damage to the first and second light-emitting diodes LED1 and LED2 when the display panel 10 is stretched.

Each of the first light-emitting diode LED1 and the second light-emitting diode LED2 may have a first height h1 in a third direction (e.g., a z-direction or a thickness direction of the display panel 10). Each of the first connection line WL1, the first electrode pad 241, and the second electrode pad 242 may have a lower surface (e.g., a surface in the −z direction) facing the base layer EL1, and an upper surface (e.g., a surface in the +z direction) opposite the lower surface. The upper surface of the first connection line WL1 may protrude in the third direction (e.g., the z-direction) from the upper surface of the first electrode pad 241 and the upper surface of the second electrode pad 242. For example, the upper surface of the first connection line WL1 may have a second height h2 based on the upper surfaces of the first and second electrode pads 241 and 242, and the second height h2 may be about 1% to about 200% of the first height h1. The second height h2 may be adjusted by taking into account the thickness of a resin layer of a carrier substrate that transfers the first and second light-emitting diodes LED1 and LED2.

When the first and second light-emitting diodes LED1 and LED2 are bonded to the first and second electrode pads 241 and 242, the upper surface of the first connection line WL1 may be in contact with the lower surface (e.g., a surface in the −z direction) of the resin layer of the carrier substrate. Because the upper surface of the first connection line WL1 protrudes from the upper surface of the first electrode pad 241 and the upper surface of the second electrode pad 242, even when a transfer substrate is not uniformly pressed, the pressure concentrated in a certain area may be distributed, thereby preventing over-compression of the bonding layers BD.

In one or more embodiments, as shown in FIG. 6B-6D, the upper surface of the first electrode pad 241 and the upper surface of the second electrode pad 242 may be arranged at different levels. In this case, the second height h2 may be determined based on a higher surface (a surface farthest from the base layer EL1) between the upper surface of the first electrode pad 241 and the upper surface of the second electrode pad 242.

A cover layer EL2 may be arranged over the first and second light-emitting diodes LED1 and LED2, the protective layer 240, and the first connection line WL1. The cover layer EL2 may include an elastic polymer. For example, the cover layer EL2 may include thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, PDMS, and/or ecoflex.

The cover layer EL2 may cover the first and second light-emitting diodes LED1 and LED2 and the first connection line WL1. The cover layer EL2 may absorb stress that may be transmitted to the first and second light-emitting diodes LED1 and LED2 and the first connection line WL1 when the display panel 10 is stretched, and may planarize the upper surface of the display panel 10.

The base layer EL1 may fill the opening OPa, and in the second area 12, the level of the upper surface (e.g., a surface in the +z direction) of the base layer EL1 may be substantially equal to the upper surface of an organic insulating layer OIL, for example, the upper surface (e.g., a surface in the +z direction) of the second organic insulating layer OIL2. The second area 12 where no inorganic insulating layers IIL and organic insulating layers OIL are present may be relatively easily transformed. In the second area 12, the lower surface (e.g., a surface in the −z direction) of the first connection line WL1 may be in direct contact with the upper surface of the base layer EL1. The upper surface (e.g., a surface in the +z direction) and side surfaces of the first connection line WL1 may be in direct contact with the cover layer EL2.

In one or more embodiments, the cover layer EL2 may be in direct contact with a portion of the upper surface of the base layer EL1, which is exposed from the protective layer 240 and the first and second connection lines WL1 and WL2. In one or more embodiments, when the material of the base layer EL1 and the material of the cover layer EL2 are the same, the bonding strength between the base layer EL1 and the cover layer EL2 may increase, thereby improving the sealability of the display panel 10.

FIG. 8 illustrates that the first connection line WL1 electrically connects the data line DL of the first pixel circuit layer PCL1 and the data line DL of the second pixel circuit layer PCL2 to each other, but the present disclosure is not limited thereto. Each of signal lines and/or voltage lines electrically connected to the pixels PX (see FIG. 4) in the same row or the same column may be electrically connected via a connection line having a structure identical or similar to that of the first connection line WL1.

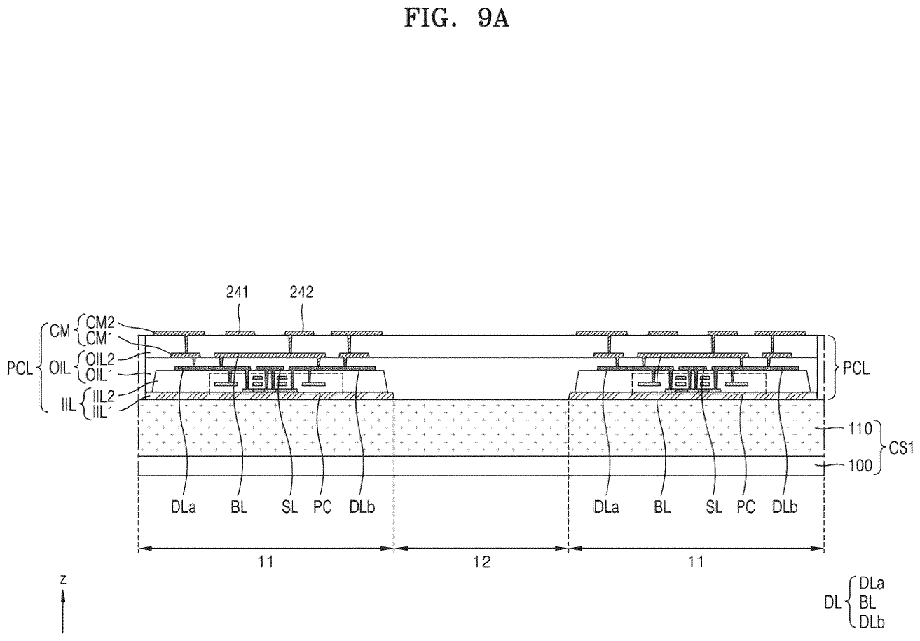

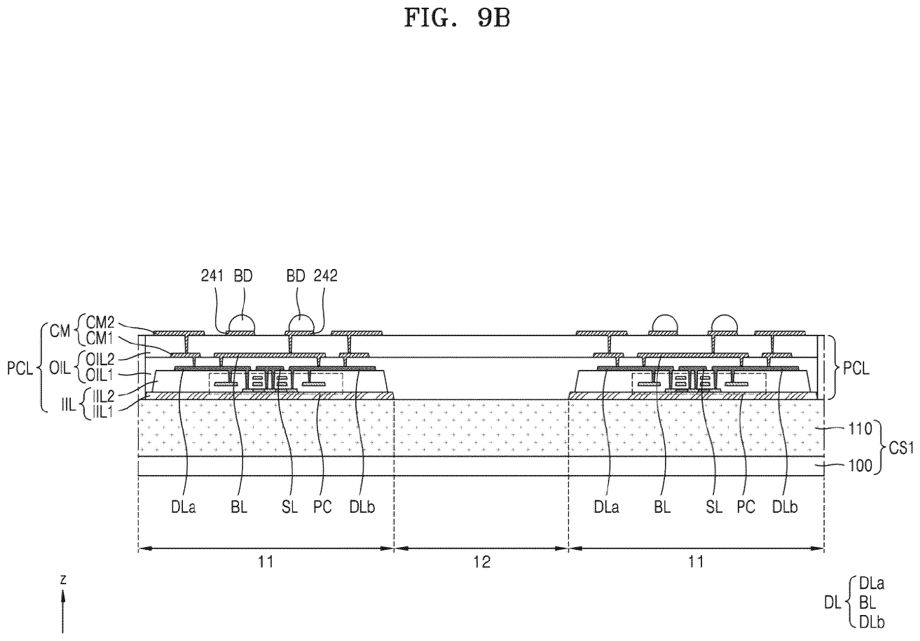

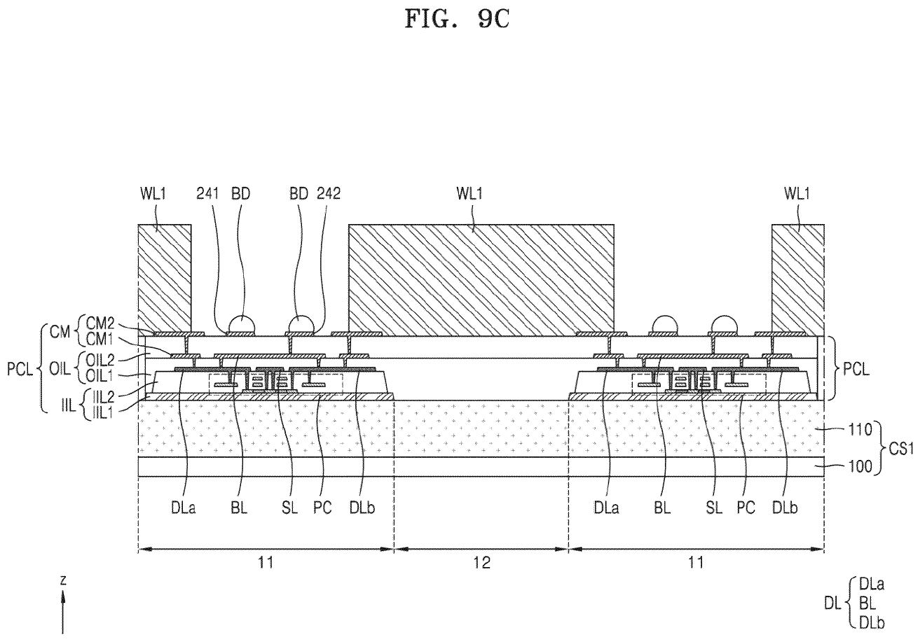

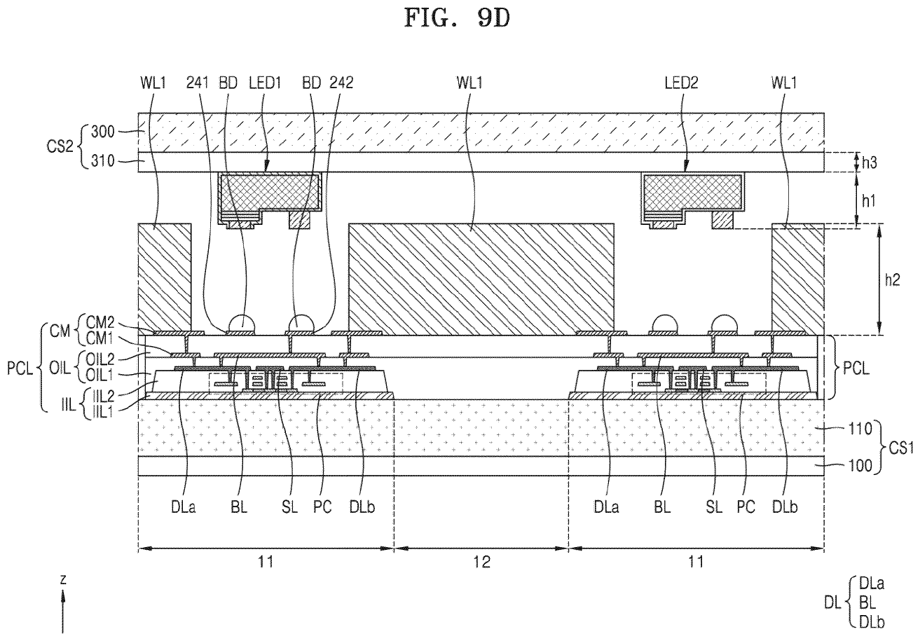

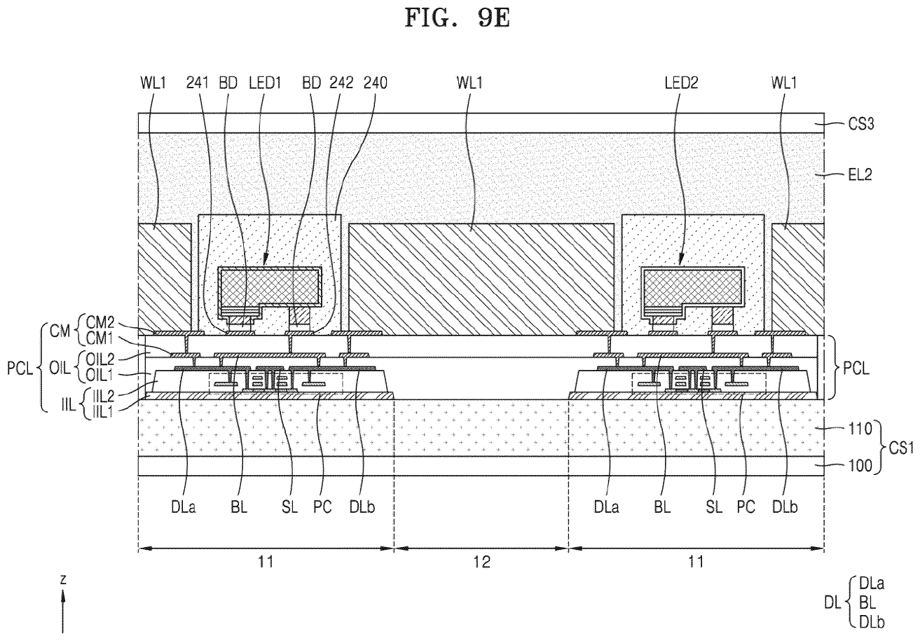

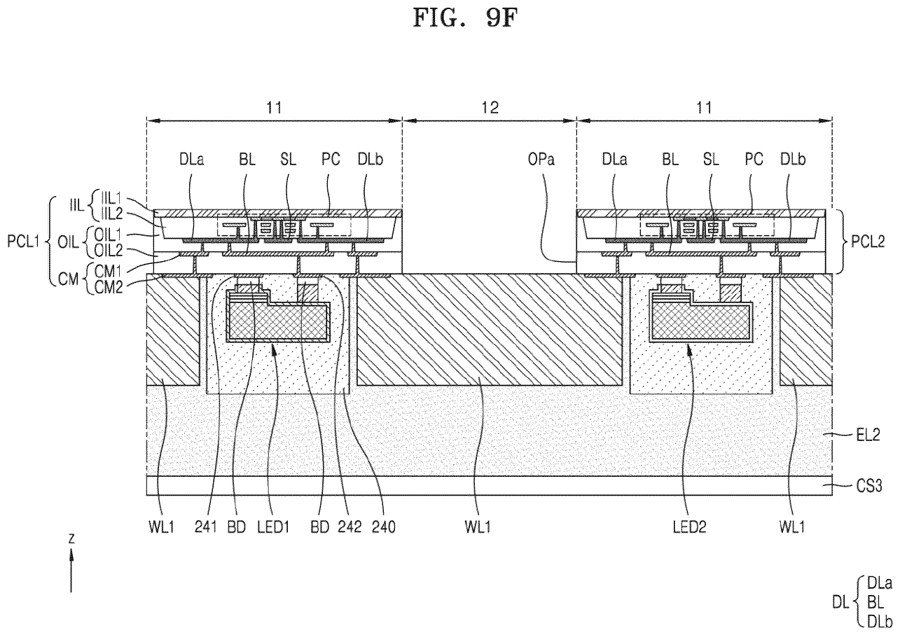

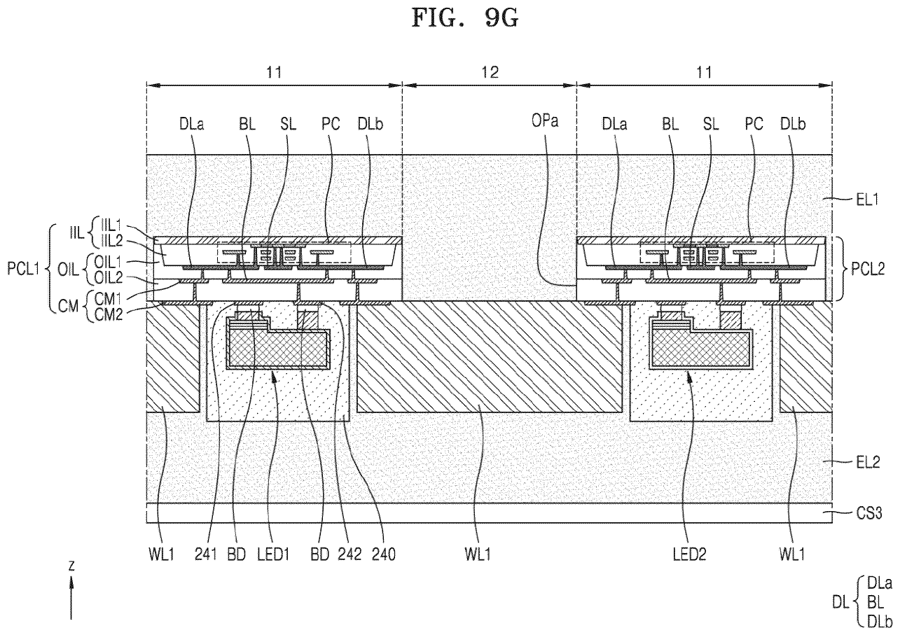

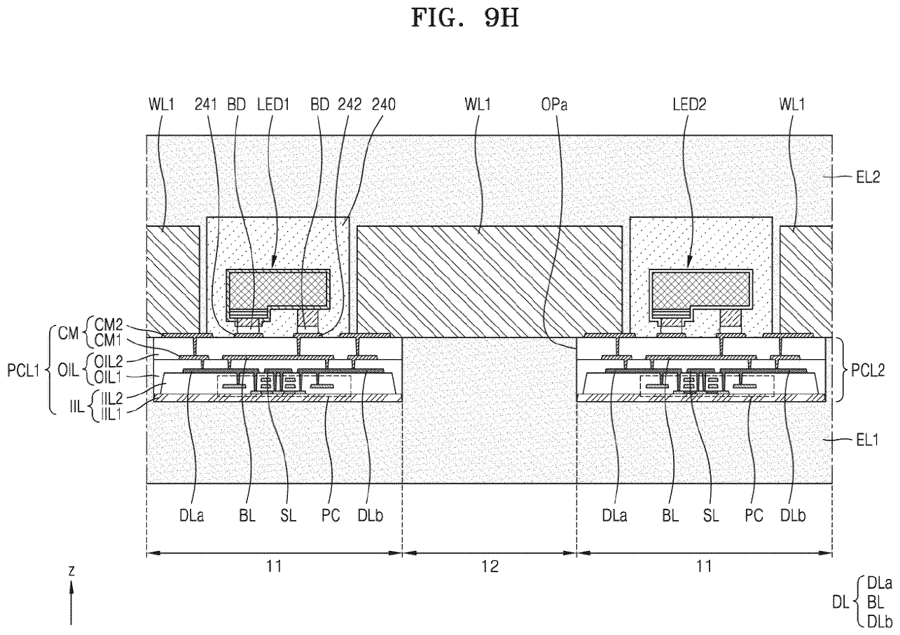

FIG. 9A-9H are cross-sectional views showing a process based on a method of manufacturing a display panel, according to one or more embodiments.

Referring to FIG. 9A, a first carrier substrate CS1 may be prepared. In one or more embodiments, the first carrier substrate CS1 may include a first substrate 100 and a first resin layer 110 arranged on the first substrate 100. The first substrate 100 may include a rigid substrate. For example, the first substrate 100 may include a transparent glass substrate including silicon oxide as a main component, or a substrate including a polymer resin material such as reinforced plastic. The first resin layer 110 may include a polymer resin. For example, the first resin layer 110 may include polyethersulfone, polyacrylate, polyether imide, polyethylene naphthalate, polyethylene terephthalate, polyphenylene sulfide, polyarylate, polyimide, polycarbonate, and/or cellulose acetate propionate. In one or more embodiments, the thickness of the first resin layer 110 may be greater than the thickness of the first substrate 100.

A pixel circuit layer PCL may be formed on the first carrier substrate CS1. The pixel circuit layer PCL may include inorganic insulating layers IIL, organic insulating layers OIL, pixel circuits PC, lines DL and SL, electrode pads 241 and 242, and connection electrodes CM. The inorganic insulating layers IIL may include a first inorganic insulating layer IIL1 arranged below a pixel circuit PC, and second inorganic insulating layers IIL2 between semiconductor layers and conductive layers that constitute the pixel circuit PC. The organic insulating layers OIL may include a first organic insulating layer OIL1 arranged on the inorganic insulating layers IIL, and a second organic insulating layer OIL2 arranged on the first organic insulating layer OIL1.

Each of the first contact electrodes CM1 may be connected to a first portion DLa or a second portion DLb of a data line DL via a contact hole passing through the first organic insulating layer OIL1. Each of the second contact electrodes CM2 may be connected to a first contact electrode CM1 via a contact hole passing through the second organic insulating layer OIL2. A bridge line BL may electrically connect the first portion DLa and the second portion DLb of the data line DL to each other.

The inorganic insulating layers IIL may be arranged only in a first area 11 and not in a second area 12. For example, a portion of the first area 11 overlapping the second area 12 may be removed through an etching process.

Referring to FIG. 9B, bonding layers BD may be formed on first electrode pads 241 and second electrode pads 242. The bonding layers BD may be formed by being patterned to overlap the first electrode pads 241 and the second electrode pads 242, respectively.

Referring to FIG. 9C, a first connection line WL1 that electrically connects data lines DL to each other may be formed, the data lines DL being arranged in two adjacent first areas 11. The first connection line WL1 may be arranged in the second area 12 between the two adjacent first areas 11 and may extend from one of the two adjacent first areas 11 toward the other across the second area 12.

The data line DL arranged in one first area 11 may be referred to as a first line, and the data line DL arranged in the other first area 11 may be referred to as a second line. One end of the first connection line WL1 may be formed to be in contact with a second contact electrode CM2 electrically connected to the first line, and the other end of the first connection line WL1 may be formed to be in contact with a second contact electrode CM2 electrically connected to the second line.

In one or more embodiments, the first connection line WL1 may include a liquid metal or may include a conductive composite material including a metal nanostructure, an elastic polymer, and/or an elastomer. The first connection line WL1 may be formed by using a deposition process, a screen printing process, an inkjet printing process, a coating process, and/or the like. The upper surface of the first connection line WL1 may protrude in a third direction (e.g., a z-direction) from the upper surface of the first electrode pad 241 and the upper surface of the second electrode pad 242.

Referring to FIG. 9D, a first light-emitting diode LED1 may be attached to the first and second electrode pads 241 and 242 arranged in one first area 11 by using a second carrier substrate CS2, and a second light-emitting diode LED2 may be attached to the first and second electrode pads 241 and 242 arranged in the other first area 11.

The second carrier substrate CS2 may include a second substrate 300 and a second resin layer 310 arranged on the lower surface (e.g., a surface facing the first carrier substrate CS1) of the second substrate 300. The second substrate 300 may include a rigid substrate. For example, the second substrate 300 may include a transparent glass substrate including silicon oxide as a main component, or a substrate including a polymer resin material such as reinforced plastic. The second resin layer 310 may include an elastic polymer. For example, the second resin layer 310 may include thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, PDMS, and/or ecoflex.

The first and second light-emitting diodes LED1 and LED2 may be repeatedly arranged on the lower surface (e.g., a surface facing the first carrier substrate CS1) of the second resin layer 310 along the first direction (e.g., an x-direction) and the second direction (e.g., a y-direction). Each of the first and second light-emitting diodes LED1 and LED2 may be arranged so that the first electrode 235 (see FIG. 6A) and the second electrode 238 (see FIG. 6A) correspond to the first electrode pad 241 and the second electrode pad 242. The first and second light-emitting diodes LED1 and LED2 may be moved by being attached to the second resin layer 310 of the second carrier substrate CS2 so that the first electrode 235 and the second electrode 238 face the first carrier substrate CS1.

The first and second light-emitting diodes LED1 and LED2 are bonded to the first and second electrode pads 241 and 242 corresponding thereto by pressing the second carrier substrate CS2. When the second carrier substrate CS2 is pressed, the first connection line WL1 may be in contact with the second resin layer 310. That is, the upper surface of the first connection line WL1 is in contact with the lower surface of the second resin layer 310 and may function as a spacer that uniformly distributes the pressure of the second carrier substrate CS2.

Each of the first light-emitting diode LED1 and the second light-emitting diode LED2 may have a first height h1 in the third direction (e.g., the z-direction), and the second resin layer 310 may have a third height h3 in the third direction (e.g., the z-direction). The upper surface of the first connection line WL1 may have a second height h2 based on the upper surfaces of the first and second electrode pads 241 and 242. As the third height h3 increases, the second height h2 may decrease or vice versa. That is, as the thickness of the second resin layer 310 becomes thinner, the thickness of the first connection line WL1 increases such that the pressure may be uniformly distributed when the second carrier substrate CS2 is pressed. The second height h2 may be about 1% to about 200% of the first height h1.

In one or more embodiments, a Young's modulus of the first connection line WL1 may be greater than a Young's modulus of the second resin layer 310. The Young's modulus of the first connection line WL1 may be about 100% to about 300% of the Young's modulus of the second resin layer 310.

Referring to FIG. 9E, the second carrier substrate CS2 may be removed, and a protective layer 240 covering each of the first and second light-emitting diodes LED1 and LED2 may be formed. After the protective layer 240 is formed, a cover layer EL2 covering the first and second light-emitting diodes LED1 and LED2, protective layers 240, and first connection lines WL1 may be formed. The cover layer EL2 may be in direct contact with the upper surface (e.g., a surface in a +z direction) and side surfaces of the first connection line WL1. The cover layer EL2 may be formed by coating a material (e.g., an elastic polymer) forming the cover layer EL2 and curing the same. A curing process may use heat or light such as ultraviolet (UV) light.

A third carrier substrate CS3 may be attached on the cover layer EL2. In one or more embodiments, the third carrier substrate CS3 may include a rigid substrate. For example, the third carrier substrate CS3 may include a transparent glass substrate including silicon oxide as a main component, or a substrate including a polymer resin material such as reinforced plastic.

Referring to FIG. 9F, the first carrier substrate CS1 may be removed, and an opening OPa may be formed by removing a portion of the pixel circuit layer PCL overlapping the second area 12. First, in the structure according to the process of FIG. 9E, the first substrate 100 may be removed from the first resin layer 110 by irradiating laser to the lower surface (e.g., a surface in a −z direction) of the first carrier substrate CS1. Thereafter, after the structure from which the first substrate 100 has been removed is reversed upside down, a portion of the pixel circuit layer PCL overlapping the second area 12 and the first resin layer 110 may be removed through a dry etching process. In this case, because the etching rate of a second inorganic insulating layer IIL2 is lower than the etching rate of the organic insulating layers OIL, the second inorganic insulating layer IIL2 may function as a mask. Accordingly, the pixel circuit layer PCL overlapping first areas 11 is not etched, and the first pixel circuit layer PCL1 and the second pixel circuit layer PCL2 having an isolated shape may be formed. The opening OPa may be formed by removing a portion of the pixel circuit layer PCL overlapping the second area 12. The opening OPa may surround each of the first pixel circuit layer PCL1 and the second pixel circuit layer PCL2 in a plan view.

Referring to FIG. 9G, a base layer EL1 may be formed on the structure of FIG. 9F. The base layer EL1 may be arranged to cover the first pixel circuit layer PCL1 and the second pixel circuit layer PCL2. The base layer EL1 may fill the opening OPa. The base layer EL1 may be in direct contact with one surface of the first connection line WL1 via the opening OPa. In one or more embodiments, the base layer EL1 may be in direct contact with a portion of the cover layer EL2. The base layer EL1 may support components of the display panel 10 (see FIG. 1) and absorb stress generated when the display panel 10 is stretched.

Referring to FIG. 9H, the display panel 10 as shown in FIG. 8 may be formed by reversing the structure of FIG. 9G again and removing the third carrier substrate CS3. The third carrier substrate CS3 may be removed through a laser lift-off process or by using a peeling tape.

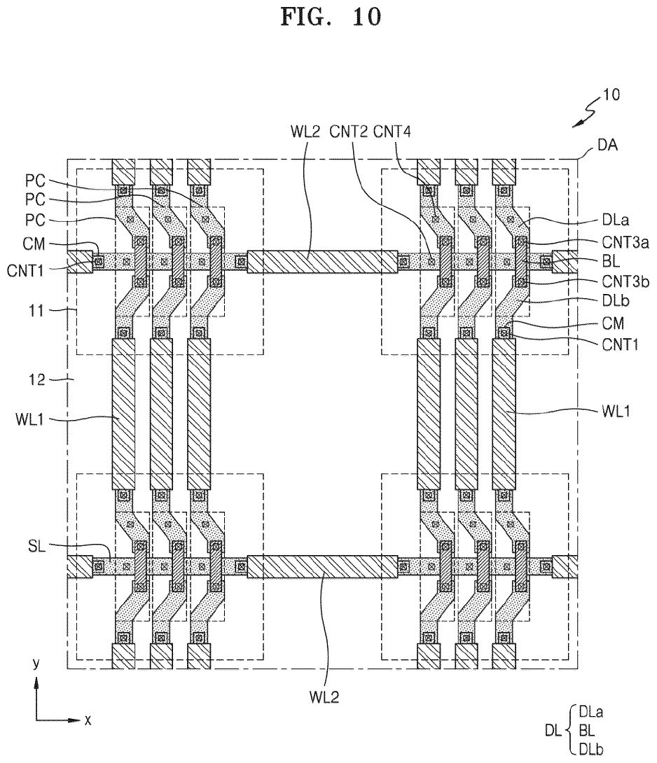

FIG. 10 is a schematic plan view of a portion of the display area DA of the display panel 10, according to one or more embodiments.

Referring to FIG. 10, two or more pixels PX may be arranged in the first area 11. Each pixel PX may include the light-emitting diode LED (see FIG. 5A). In one or more embodiments, the display 10 (see FIG. 1) may have an active matrix structure, and each pixel PX may include the pixel circuit PC (see FIG. 5D) electrically connected to the light-emitting diode LED. The pixel circuit PC may include transistors and capacitors.

The first area 11 may have a smaller elongation than that of the second area 12. The first area 11 is an area where light-emitting diodes are arranged, and may be referred to as a pixel area or an emission area. The second area 12 may surround the first area 11 and have a larger elongation than that of the first area 11. The second area 12 is an area of the display area where no light-emitting diode is arranged, and may be referred to as a non-pixel area or a non-emission area.

Signal lines and/or voltage lines may be arranged in the display area DA. FIG. 10 illustrates that the scan line SL and the data line DL are each arranged in the first area 11, but the present disclosure is not limited thereto. Various signal lines and voltage lines may be further arranged in the first area 11, and additional connection lines that connect the signal lines and the voltage lines may be further arranged in the second area 12.

In one or more embodiments, the scan line SL may be electrically connected to a gate electrode of a transistor included in the pixel circuit PC via the second contact hole CNT2. The data line DL may be electrically connected to one terminal of a transistor included in a corresponding pixel circuit PC via the fourth contact hole CNT4. In another embodiment, the scan line SL may be electrically connected to the first electrode pad 241 (see FIG. 6A) via the second contact hole CNT2, and the data line DL may be electrically connected to the second electrode pad 242 (see FIG. 6B) via the fourth contact hole CNT4.

Three data lines DL may be arranged in one first area 11. Corresponding data lines DL respectively arranged in two first areas 11 adjacent in a second direction (e.g., a y-direction) may be electrically connected to each other by a connection line (hereinafter referred to as the first connection line WL1). The first connection line WL1 may be arranged in the second area 12 and extend in the second direction (e.g., the y-direction). The first connection line WL1 may be connected to the data lines DL via the contact electrodes CM and the first contact holes CNT1.

Scan lines SL respectively arranged in two first areas 11 adjacent in a first direction (e.g., an x-direction) may be electrically connected to each other by a connection line (hereinafter referred to as the second connection line WL2). The second connection line WL2 may be arranged in the second area 12 and extend in the first direction (e.g., the x-direction). The second connection line WL2 may be connected to the scan lines SL via the contact electrodes CM and the first contact holes CNT1.

The scan line SL and the data line DL may cross each other in the first area 11. In one or more embodiments, the data line DL may include the first portion DLa and the second portion DLb separated from each other with the scan line SL therebetween, and the bridge line BL that electrically connects the first portion DLa and the second portion DLb to each other. The bridge line BL may be arranged in an area where the data line DL and the scan line SL cross each other, and may be arranged on a different layer from the scan line SL. In one or more embodiments, the first portion DLa and the second portion DLb of the data line DL and the scan line SL may be arranged on (or at) the same layer, one end of the bridge line BL may be connected to the first portion DLa via the third-1 contact hole CNT3a, and the other end of the bridge line BL may be connected to the second portion DLb via the third-2 contact hole CNT3b.

The first and second connection lines WL1 and WL2 arranged in the second area 12 may be stretched better than lines arranged in the first area 11, for example, the scan line SL and the data line DL. An elongation of each of the first connection line WL1 and the second connection line WL2 may be greater than an elongation of each of the scan line SL and the data line DL.

Each of the scan line SL and the data line DL may include one or more materials selected from among Al, Pt, Pd, Ag, Mg, Au, Ni, Nd, Ir, Cr, Li, Ca, Mo, Ti, W, and/or Cu. Each of the scan line SL and the data line DL may include a single layer or a plurality of layers including the aforementioned metal. In one or more embodiments, each of the scan line SL and the data line DL may include a metal thin film formed of a triple layer having a structure of Ti/Al/Ti. The first connection line WL1 and the second connection line WL2 may include a liquid metal, may include a conductive composite material including a metal nanostructure, an elastic polymer, and/or an elastomer, and/or may include a conductive polymer.

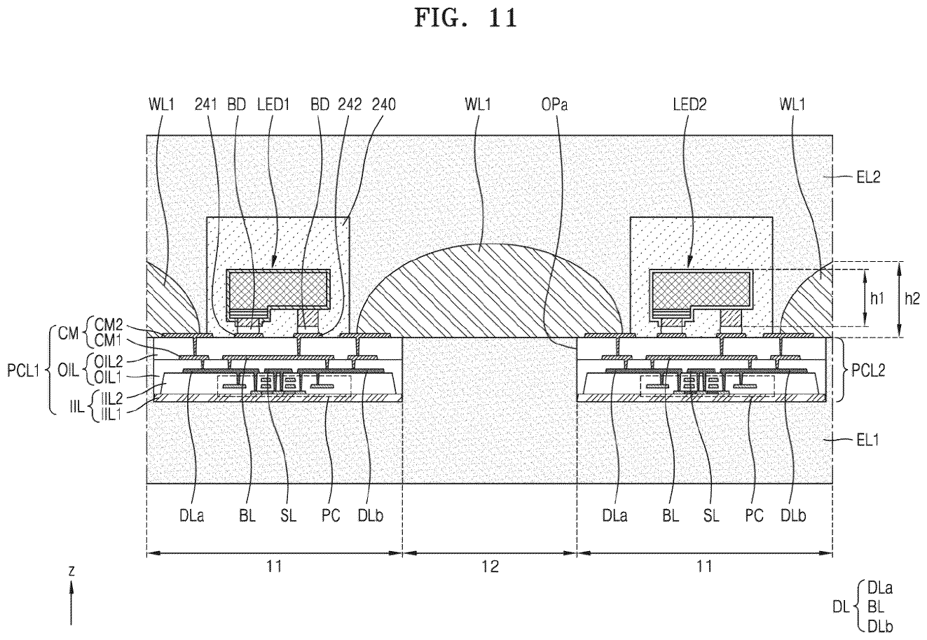

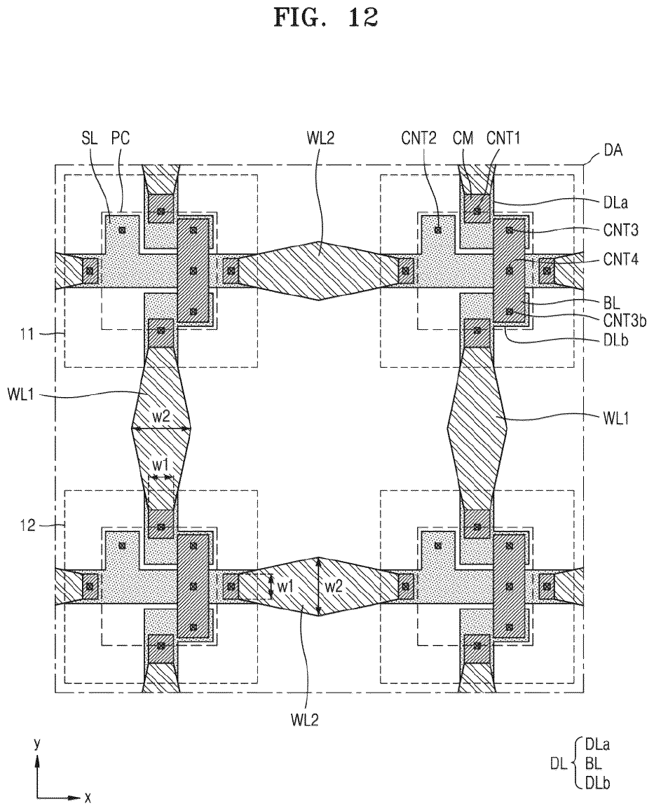

FIG. 11 is a schematic cross-sectional view of a portion of the display panel 10, according to one or more embodiments. FIG. 12 is a schematic plan view of a portion of the display area DA of the display panel 10, according to one or more embodiments.

The display panel 10 of FIG. 11 is similar to the display panel 10 shown in FIG. 8 but differs therefrom in that a cross-section of the first connection line WL1 has a shape with a convex center. Hereinafter, descriptions of identical or similar elements are omitted, and differences are mainly described.

Referring to FIG. 11, as the first connection line WL1 is further away from the light-emitting diodes LED1 and LED2, the first connection line WL1 may become thicker in a third direction (e.g., a z-direction or a thickness direction). That is, the first connection line WL1 may have a shape with a convex center, in which the first connection line WL1 becomes thicker as the first connection line WL1 is closer to an intermediate point between the first light-emitting diode LED1 and the second light-emitting diode LED2, and first connection line WL1 becomes thinner as the first connection line WL1 is closer to each of the first light-emitting diode LED1 and the second light-emitting diode LED2.

A portion of the first connection line WL1 far from the first and second light-emitting diodes LED1 and LED2 may function as a spacer by being in contact with the second resin layer 310 (see FIG. 9D) when the first and second light-emitting diodes LED1 and LED2 are bonded by pressing the second carrier substrate CS2 (see FIG. 9D). In this case, because a portion of the first connection line WL1 close to the first and second light-emitting diodes LED1 and LED2 is relatively thin, interference with a bonding process due to transformation may be reduced or prevented. This shape may be equally applied to other connection lines (e.g., the second connection line WL2).

Referring to FIG. 12, in a plan view, as the first connection line WL1 is further away from the pixel PX (or a light-emitting diode), the width of the first connection line WL1 in a direction (e.g., an x-direction) crossing an extension direction (e.g., a y-direction) of the first connection line WL1 may increase. In a plan view, as the second connection line WL2 is further away from the pixel PX (or a light-emitting diode), the width of the second connection line WL2 in a direction (e.g., the y-direction) crossing an extension direction (e.g., the x-direction) of the second connection line WL2 may increase.

For example, the first connection line WL1 may have a first width w1 in a first direction (e.g., the x-direction) at both ends thereof close to the pixel PX and may have a second width w2 in the first direction (e.g., the x-direction) at an intermediate point between the pixels PX being connected. Similarly, the second connection line WL2 may have a first width w1 in a second direction (e.g., the y-direction) at both ends thereof close to the pixel PX and may have a second width w2 in the second direction (e.g., the y-direction) at the intermediate point between the pixels PX being connected. The second width w2 may be greater than the first width w1.

A material that forms the first connection line WL1 and the second connection line WL2 may shrink due to surface tension and have a large height at the intermediate point between the pixels PX having a large width. Accordingly, as shown in FIG. 11, a convex shape in which the thickness increases in the third direction (e.g., the z-direction or the thickness direction) as the first and the second connection line WL1 and WL2 are further away from the first and second light-emitting diodes LED1 and LED2 may be formed more easily.

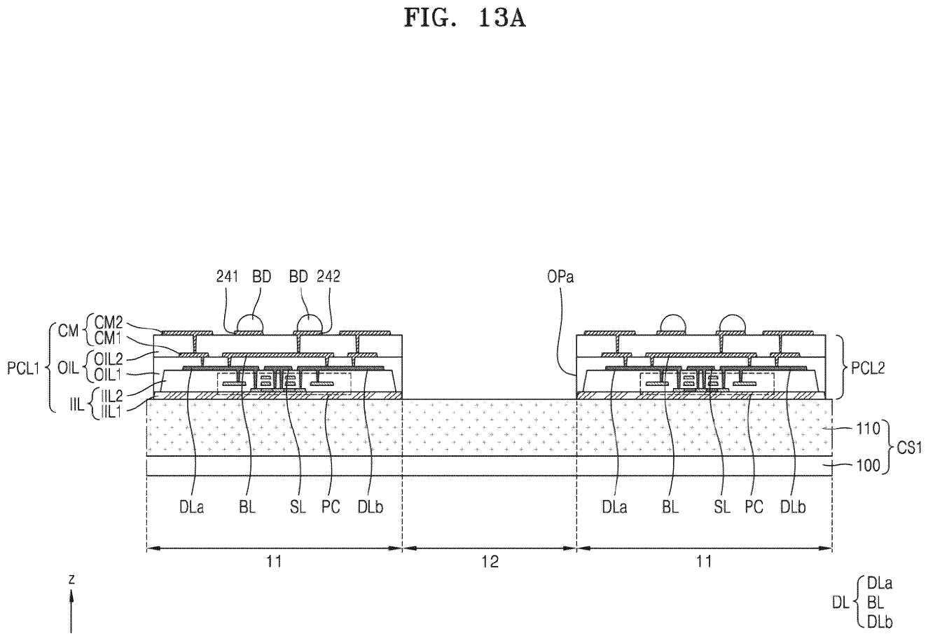

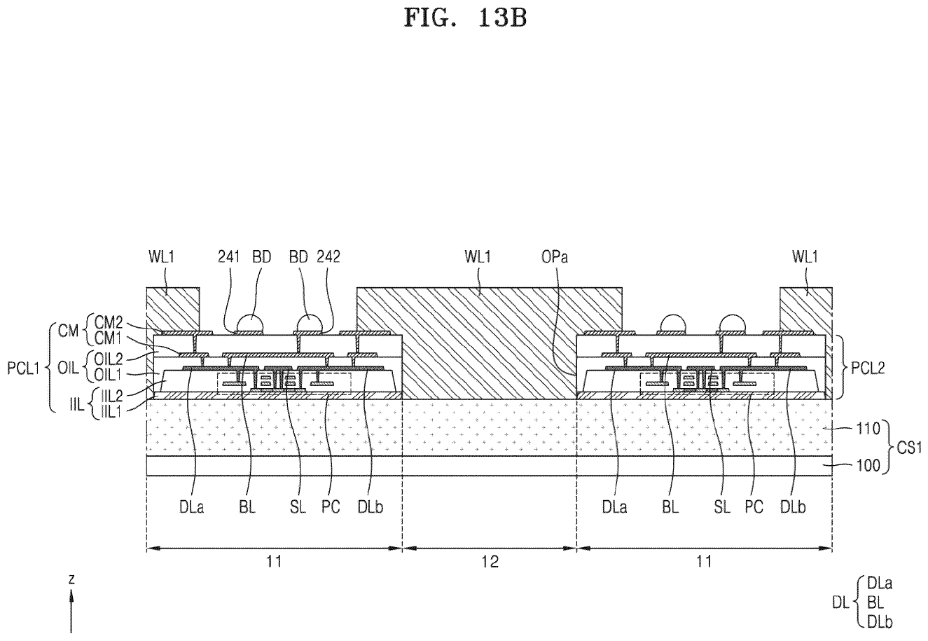

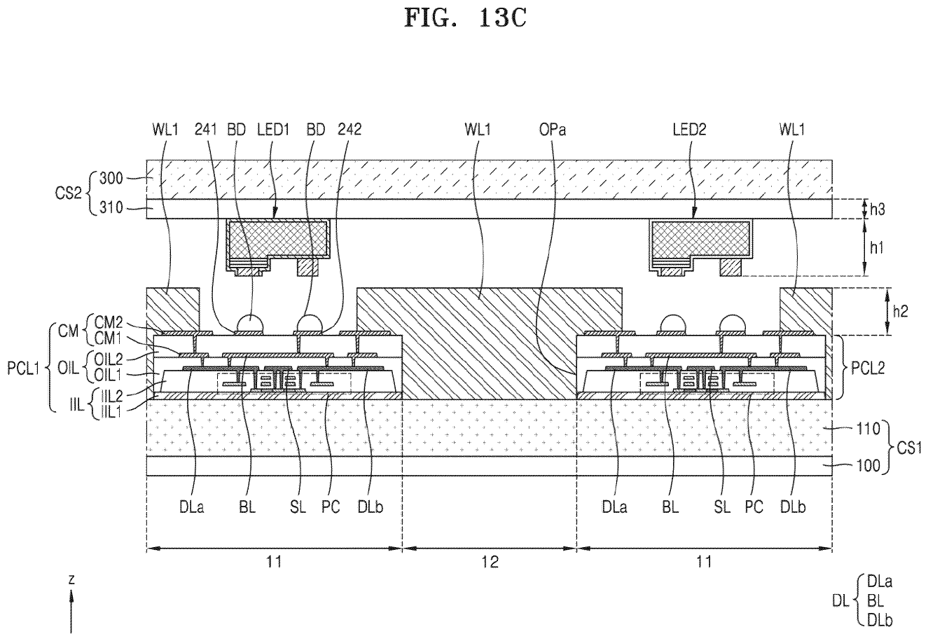

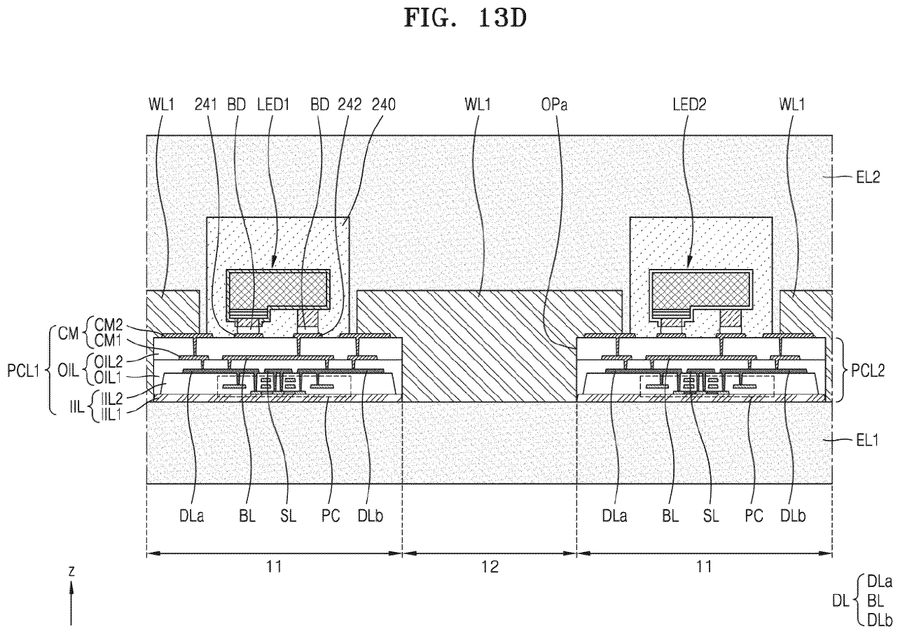

FIG. 13A-13D are cross-sectional views showing a process based on a method of manufacturing a display panel, according to one or more embodiments.

Referring to FIG. 13A, in the structure of FIG. 9A, an opening OPa may be formed by removing a portion of the pixel circuit layer PCL overlapping the second area 12 through a dry etching process. In one or more embodiments, a hard mask layer having an opening overlapping the second area 12 may be formed on the pixel circuit layer PCL, and an opening OPa may be formed by dry-etching the pixel circuit layer PCL using the hard mask layer and removing the hard mask layer. Pixel circuit layers PCL overlapping the first areas 11 are not etched, and the first pixel circuit layer PCL1 and the second pixel circuit layer PCL2 having an isolated shape may be formed. The opening OPa may surround each of the first pixel circuit layer PCL1 and the second pixel circuit layer PCL2 in a plan view.

The bonding layers BD may be formed on the first electrode pads 241 and the second electrode pads 242. The bonding layers BD may be formed by being patterned to overlap the first electrode pads 241 and the second electrode pads 242, respectively.

Referring to FIG. 13B-13C, the first connection line WL1 that electrically connects the data lines DL to each other may be formed, the data lines DL being arranged in two adjacent first areas 11. The first connection line WL1 may be arranged in the second area 12 between the two adjacent first areas 11 and may extend from one of the two adjacent first areas 11 toward the other.

The data line DL arranged in one first area 11 may be referred to as a first line, and the data line DL arranged in the other first area 11 may be referred to as a second line. One end of the first connection line WL1 may be formed to be in contact with the second contact electrode CM2 electrically connected to the first line, and the other end of the first connection line WL1 may be formed to be in contact with the second contact electrode CM2 electrically connected to the second line.

In this case, the first connection line WL1 may fill a portion of the opening OPa. For example, the lower surface (e.g., a surface in a −z direction) of the first connection line WL1 may be in direct contact with the first resin layer 110 via the opening OPa. Accordingly, the first connection line WL1 may be prevented from protruding excessively from the upper surfaces of the first and second electrode pads 241 and 242. Also, as the first connection line WL1 is in direct contact with side surfaces of the organic insulating layers OIL via the opening OPa, the connection of the first connection line WL1 with the first pixel circuit layer PCL1, and the second pixel circuit layer PCL2 may be strengthened.

Referring to FIG. 13C, the first light-emitting diode LED1 may be attached to the first and second electrode pads 241 and 242 arranged in one first area 11 by using the second carrier substrate CS2, and the second light-emitting diode LED2 may be attached to the first and second electrode pads 241 and 242 arranged in the other first area 11.

The second carrier substrate CS2 may include the second substrate 300 and the second resin layer 310 arranged on the lower surface (e.g., a surface facing the first carrier substrate CS1) of the second substrate 300. The second substrate 300 may include a rigid substrate. For example, the second substrate 300 may include a transparent glass substrate including silicon oxide as a main component, or a substrate including a polymer resin material such as reinforced plastic. The second resin layer 310 may include an elastic polymer.

The first and second light-emitting diodes LED1 and LED2 may be repeatedly arranged on the lower surface (e.g., a surface facing the first carrier substrate CS1) of the second resin layer 310 along the first direction (e.g., an x-direction) and the second direction (e.g., a y-direction). Each of the first and second light-emitting diodes LED1 and LED2 may be arranged so that the first electrode 235 (see FIG. 6A) and the second electrode 238 (see FIG. 6A) correspond to the first electrode pad 241 and the second electrode pad 242.

The first and second light-emitting diodes LED1 and LED2 are bonded to the first and second electrode pads 241 and 242 corresponding thereto by pressing the second carrier substrate CS2. When the second carrier substrate CS2 is pressed, the first connection line WL1 may be in contact with the second resin layer 310. That is, the upper surface of the first connection line WL1 is in contact with the lower surface of the second resin layer 310 and may function as a spacer of the second carrier substrate CS2.

Each of the first light-emitting diode LED1 and the second light-emitting diode LED2 may have a first height h1 in a third direction (e.g., a z-direction), and the second resin layer 310 may have a third height h3 in the third direction (e.g., the z-direction). The upper surface of the first connection line WL1 may have a second height h2 based on the upper surfaces of the first and second electrode pads 241 and 242. As the third height h3 increases, the second height h2 may decrease or vice versa. That is, as the thickness of the second resin layer 310 becomes thinner, the thickness of the first connection line WL1 increases such that the pressure may be uniformly distributed when the second carrier substrate CS2 is pressed. The second height h2 may be about 1% to about 200% of the first height h1.

In one or more embodiments, a Young's modulus of the first connection line WL1 may be greater than a Young's modulus of the second resin layer 310. The Young's modulus of the first connection line WL1 may be about 100% to about 300% of the Young's modulus of the second resin layer 310.

Referring to FIG. 13D, the second carrier substrate CS2 may be removed, and the protective layer 240 covering each of the first and second light-emitting diodes LED1 and LED2 may be formed. After the protective layer 240 is formed, the cover layer EL2 covering the first and second light-emitting diodes LED1 and LED2, protective layers 240, and first connection lines WL1 may be formed. The cover layer EL2 may be in direct contact with the upper surface (e.g., a surface in a +z direction) and side surfaces of the first connection line WL1. Thereafter, the first carrier substrate CS1 and the first resin layer 110 may be removed, and the base layer EL1 may be formed. The base layer EL1 may be arranged to cover the lower surfaces (e.g., surfaces in the −z direction) of the first pixel circuit layer PCL1 and the second pixel circuit layer PCL2. As described above with reference to FIG. 9G, a structure in which the cover layer EL2 is formed is attached to the third carrier substrate CS3 and reversed upside down such that the first resin layer 110 may be removed, and the base layer EL1 may be formed. The base layer EL1 may be in direct contact with one surface of the first connection line WL1 filling the opening OPa. The base layer EL1 may be in direct contact with a portion of the cover layer EL2.

FIG. 13A-13D illustrate that the opening OPa is formed by etching both the first organic insulating layer OIL1 and the second organic insulating layer OIL2, but the present disclosure is not limited thereto. A groove corresponding to a planar shape of the first connection line WL1 may be formed by etching only a portion of the organic insulating layers OIL. In this case, similar to the process as described with reference to FIG. 9F, the opening OPa may be formed in a process of removing the first carrier substrate CS1.

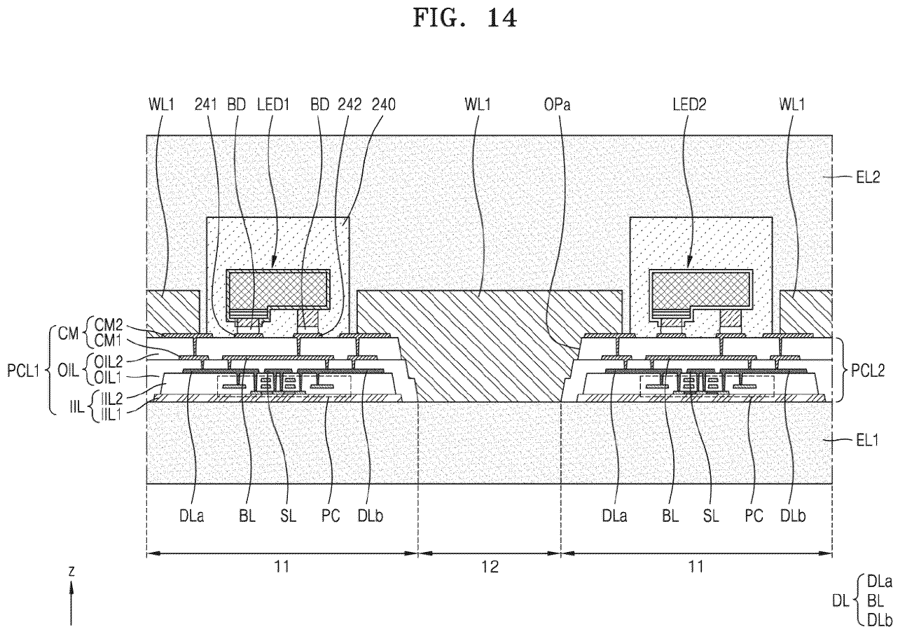

FIG. 14 is a schematic cross-sectional view of a portion of a display panel, according to one or more embodiments. FIG. 14 is similar to FIG. 13D but differs therefrom in that the side surface of the opening OPa has a stepped shape.

Referring to FIG. 14, the organic insulating layers OIL forming the side of the opening OPa may have steps with respect to the upper surface (e.g., a surface in the +z direction) of the base layer EL1. For example, the first organic insulating layer OIL1 may have a stepped cross-section corresponding to the inorganic insulating layers IIL having steps. An end of the first organic insulating layer OIL1 may be arranged closer to the center of the opening OPa than an end of the second organic insulating layer OIL2. This structure may be formed by patterning each of the first organic insulating layer OIL1 and the second organic insulating layer OIL2. For example, the first organic insulating layer OIL1 may be formed by being patterned to correspond to the inorganic insulating layers IIL, and the second organic insulating layer OIL2 may be formed by being patterned to correspond to the first organic insulating layer OIL1. The first organic insulating layer OIL1 may cover side surfaces of the inorganic insulating layers IIL.

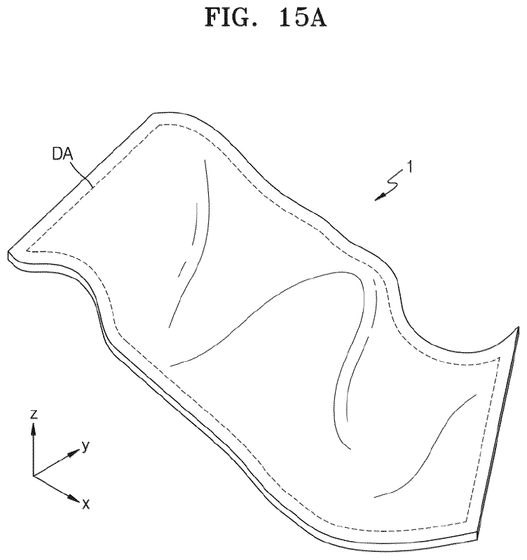

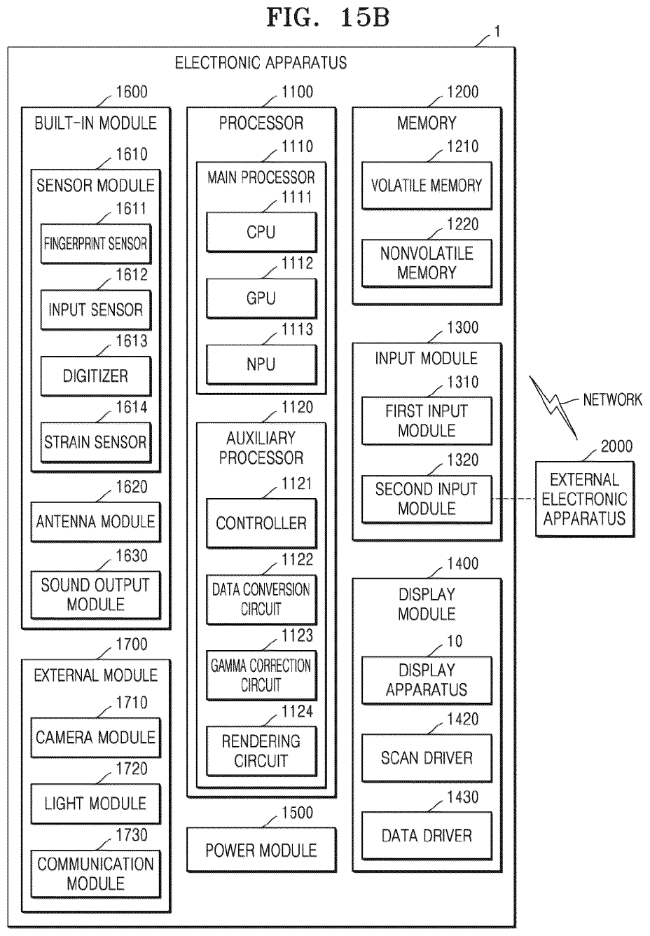

FIG. 15A is a schematic perspective view of an electronic apparatus 1 including a display panel, according to one or more embodiments, and FIG. 15B is a block diagram of the electronic apparatus 1 including a display panel, according to one or more embodiments.

Referring to FIG. 15A, the electronic apparatus 1 may be freely transformed in three dimensions and provide a three-dimensional image surface through the display area DA. When the electronic apparatus 1 is freely transformed in three dimensions, this is distinguished from the operation of an electronic apparatus having a rollable display apparatus, such as a case where a portion of a rolled-up display area is visible to a user and then another portion of the rolled-up display area is unfolded to reveal the entire display area to the user (or a case where the entire unfolded display area is visible to the user and then the display area is rolled up to reveal only a portion of the display area to the user). The electronic apparatus 1 according to one or more embodiments may exhibit transformation, such as the area of the entire display area DA increasing or decreasing again as the electronic apparatus 1 is transformed in an x-direction, a y-direction, and/or a z-direction.

Referring to FIG. 15B, the electronic apparatus 1 may include a processor 1100, a memory 1200, an input module 1300, a display module 1400, a power module 1500, a built-in module 1600, and an external module 1700. According to one or more embodiments, in the electronic apparatus 1, at least one of the aforementioned components may be omitted, or one or more other components may be added. According to one or more embodiments, some (e.g., the built-in module 1600) of the aforementioned components may be integrated into another component (e.g., the display module 1400).

The processor 1100 may execute software to control at least one other component (e.g., a hardware or software component) of the electronic apparatus 1 connected to the processor 1100, and may perform various data processing or operations. According to one or more embodiments, as at least a portion of data processing or operation, the processor 1100 may store, in a volatile memory 1210, commands or data received from another component (e.g., the input module 1300, a sensor module 1610, or a communication module 1730), process the commands or data stored in the volatile memory 1210), and store result data in a nonvolatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one of a graphic processing unit (GPU) 1112, a communication processor (CP), or an image signal processor (ISP). The main processor 1110 may further include a neural processing unit (NPU) 1113. The NPU 1113 is a processor specialized in processing an artificial intelligence model, and the artificial intelligence model may be generated through machine learning. The artificial intelligence model may include a plurality of artificial neural network layers. An artificial neural network may include one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or any combinations of two or more of the aforementioned networks, but is not limited to the examples described above. The artificial intelligence model may additionally or alternatively include a software structure in addition to a hardware structure. At least two of the processing units or processors described above may be implemented as a single integrated component (e.g., a single chip) or may each be implemented as an independent component (e.g., a plurality of chips).

The auxiliary processor 1120 may include a controller 1121. The controller 1121 may include an interface conversion circuit and a timing control circuit. The controller 1121 receives an image signal from the main processor 1110, converts the data format of the image signal to match interface specifications of the display module 1400, and outputs image data. The controller 1121 may output various control signals necessary for driving the display module 1400.

The auxiliary processor 1120 may further include data processing circuits such as a data conversion circuit 1122, a gamma correction circuit 1123, and a rendering circuit 1124. The data conversion circuit 1122 may receive the image data from the controller 1121 and may compensate for the image data so that an image is displayed at a desired brightness according to characteristics of the electronic apparatus 1 or user settings, or may convert the image data to reduce power consumption or compensate for an afterimage. The gamma correction circuit 1123 may convert the image data or a gamma reference voltage so that an image displayed on the electronic apparatus 1 has desired gamma characteristics. The rendering circuit 1124 may receive image data from the controller 1121 and render the image data by taking into consideration a pixel layout of the display panel 10 applied to the electronic apparatus 1. At least one of the data conversion circuit 1122, the gamma correction circuit 1123, or the rendering circuit 1124 may be integrated into another component (e.g., the main processor 1110 or the controller 1121). In one or more embodiments, the auxiliary processor 1120 may be integrated into a data driver 1430.

The memory 1200 may store various types of data used by at least one component (e.g., the processor 1100 or the sensor module 1610) of the electronic apparatus 1, and input data or output data for commands related thereto. The memory 1200 may include at least one of the volatile memory 1210 or the nonvolatile memory 1220.

The input module 1300 may receive commands or data to be used for a component (e.g., the processor 1100, the sensor module 1610, or a sound output module 1630) of the electronic apparatus 1 from an external source (e.g., a user or an external electronic apparatus 2000) of the electronic apparatus 1.

The input module 1300 may include a first input module 1310 into which commands or data are input from the user, and a second input module 1320 into which commands or data are input from the external electronic apparatus 2000.

The first input module 1310 may include a microphone, a mouse, a keyboard, and/or a pen (e.g., a passive pen or an active pen). The first input module 1310 may include a mechanical input means or a touch input means, such as a button, a dome switch, a jog wheel, or a jog switch, arranged on the rear surface or side surface of the electronic apparatus 1. The touch input means may include a touch screen layer of the display panel 10.

The second input module 1320 may be connected via wires or wirelessly to various types of external electronic apparatuses 2000 connected to the electronic apparatus 1. According to one or more embodiments, the second input module 1320 may include a high definition multimedia interface (HDMI), a universal serial bus (USB) interface, a secure digital (SD) card interface, and/or an audio interface. The second input module 1320 may include a connector capable of physically connecting the electronic apparatus 1 to the external electronic apparatus 2000, for example, an HDMI connector, a USB connector, an SD card connector, and/or an audio connector (e.g., a headphone connector). In response to the external electronic apparatus 2000 being connected to the second input module 1320, the electronic apparatus 1 may perform appropriate control related to the connected electronic apparatus 1.

The display module 1400 visually provides information to a user. The display module 1400 may include the display panel 10, a scan driver 1420, and the data driver 1430.

The display panel 10 displays (outputs) information processed by the electronic apparatus 1. The display panel 10 may display execution screen information about an application running on the electronic apparatus 1, or user interface (UI) or graphic user interface (GUI) information according to the execution screen information.

The scan driver 1420 may be mounted on the display panel 10 as a driving chip. Alternatively, the scan driver 1420 may be formed directly on the display panel 10. For example, the scan driver 1420 may include an amorphous silicon thin-film transistor (TFT) gate driver circuit (AGS), a low-temperature polycrystalline silicon (LTPS) TFT gate driver circuit, and/or an oxide semiconductor TFT gate driver circuit (OSG) embedded in the display panel 10. The scan driver 1420 receives a control signal from the controller 1121 and outputs scan signals to the display panel 10 in response to the control signal.

The display panel (display apparatus) 10 may further include an emission control driver. The emission control driver outputs an emission control signal to the display panel 10 in response to the control signal received from the controller 1121. The emission control driver may be formed separately from the scan driver 1420 or may be integrated into the scan driver 1420.

The data driver 1430 receives a control signal from the controller 1121, converts image data into data voltages in the form of analog voltages in response to the control signal, and outputs the data voltages to the display panel 10.

The data driver 1430 may be integrated with some components of the auxiliary processor 1120. For example, the data driver 1430 may be provided as a timing controller embedded driver integrated circuit (IC) including the controller 1121.

The power module 1500 supplies power to the components of the electronic apparatus 1. The power module 1500 may include a battery configured to charge a power voltage. Also, the power module 1500 includes a connection port, and the connection port may be included in the second input module 1320 to which an external charger is connected, the external charger being configured to supply power for charging the battery. Alternatively, the power module 1500 may include a wireless power transmission/reception member to enable wireless charging of the battery. The wireless power transmission/reception member may include a plurality of coil-shaped antenna radiators. The power module 1500 may include a power management IC (PMIC). The PMIC supplies optimized power to each component of the electronic apparatus 1.

The electronic apparatus 1 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include a touch sensor driver and touch electrodes of the touch screen layer of the display panel 10. The sensor module 1610 may detect an input made by the body of a user or an input made by the pen, and generate an electrical signal or a data value corresponding to the input. The sensor module 1610 may include at least one of a fingerprint sensor 1611, an input sensor 1612, or a digitizer 1613.

The fingerprint sensor 1611 may generate a data value corresponding to a fingerprint of the user. The fingerprint sensor 1611 may include either an optical fingerprint sensor or a capacitive fingerprint sensor.

The input sensor 1612 may generate a data value corresponding to coordinate information about the input made by the body of the user or the input made by the pen. The input sensor 1612 generates a data value based on a change in electrostatic capacitance due to the input. The input sensor 1612 may detect an input made by the passive pen or transmit and receive data to and from the active pen.

The input sensor 1612 may also measure a biosignal such as blood pressure, moisture, or body fat. For example, when a user touches a part of his or her body on a sensor layer or a sensing panel and does not move for a certain period of time, the input sensor 1612 may detect a biosignal based on a change in an electric field caused by the part of the body and output, to the display module 1400, information desired by the user.

The digitizer 1613 may generate a data value corresponding to the coordinate information about the input made by the pen. The digitizer 1613 generates a data value based on a change in an electromagnetic force caused by the input. The digitizer 1613 may detect an input made by the passive pen or transmit and receive data to and from the active pen.

A strain sensor 1614 may include a layer, a pattern, or lines in which a measurable physical quantity changes according to the stretching of the electronic apparatus 1. For example, the strain sensor 1614 may include lines of which resistance and/or capacitance changes due to the stretching of the display panel 10. In another embodiment, the strain sensor 1614 may include an optical layer or an optical pattern of which transmittance and/or reflectance changes due to the stretching of the display apparatus 1.

Based on a physical quantity according to the stretching of the display apparatus 1 measured by the strain sensor 1614, the electronic apparatus 1 may improve the image quality of an image implemented by the display apparatus 1 or control the display apparatus 1. An operation of controlling the display apparatus 1 may include, for example, an operation such as displaying an operation image for protecting the display apparatus 1, cutting off a voltage for driving the display apparatus 1, or stopping a stretching operation of the display apparatus 1.

In one or more embodiments, at least one of the fingerprint sensor 1611, the input sensor 1612, the digitizer 1613, or the strain sensor 1614 may be embedded in the display panel 10. For example, at least one of the fingerprint sensor 1611, the input sensor 1612, the digitizer 1613, or the strain sensor 1614 may be formed through a process that is continuous with a process of forming pixel circuits and light-emitting diodes of the display panel 10. Due to this, the display panel 10 may function as one of input modules 1300 configured to provide an input interface between the electronic apparatus 1 and a user and may also function as the display module 1400 configured to provide an output interface between the electronic apparatus 1 and the user.

In one or more embodiments, at least two of the fingerprint sensor 1611, the input sensor 1612, the digitizer 1613, and the strain sensor 1614 may be formed to be integrated into one sensing panel through the same process. The sensing panel may be between the display panel 10 and a window arranged on top of the display panel 10, but the present disclosure is not limited thereto.

The antenna module 1620 may include one or more antennas for transmitting or receiving signals or power to or from the outside. According to one or more embodiments, the communication module 1730 may transmit or receive a signal to or from an external electronic apparatus through an antenna suitable for a communication method. An antenna pattern of the antenna module 1620 may also be integrated into one component (e.g., the display panel 10) of the display module 1400 or the input sensor 1612.

The sound output module 1630 is an apparatus for outputting a sound signal to the outside of the electronic apparatus 1 and may output sound data received from the communication module 1730 or stored in the memory 1200 in a call signal reception mode, a call mode, a recording mode, a speech recognition mode, or a broadcasting mode. The sound output module 1630 may output a sound signal related to a function (e.g., a call signal reception sound, a message reception sound, or the like) performed by the electronic apparatus 1. The sound output module 1630 may include a receiver and a speaker. At least one of the receiver or the speaker may include a sound generation apparatus that is attached to the bottom of the display panel 10 and vibrates the display panel 10 to output sound. The sound generation apparatus may include a piezoelectric element or a piezoelectric actuator that contracts and expands in response to an electrical signal, or an exciter that vibrates the display panel 10 by generating a magnetic force by using a voice coil.

The camera module 1710 may capture still images or record videos. According to an embodiment, the camera module 1710 may include one or more lenses, image sensors, or ISPs. The camera module 1710 may further include an infrared camera capable of measuring the presence of a user, a location of the user, and a gaze of the user.

The light module 1720 may output a signal for notifying of the occurrence of an event by using a light source or provide light for obtaining images. In this case, examples of the occurrence of the event may include receiving a message, receiving a call signal, a missed call, an alarm, a schedule reminder, receiving an email, or notifying of battery charge capacity information. The light module 1720 may include a light-emitting diode or a xenon lamp. The light module 1720 may emit light of a single color or a plurality of colors to the front surface or rear surface of the electronic apparatus 1. The light module 1720 may operate in conjunction with the camera module 1710 or operate independently.

The communication module 1730 may support the establishment of a wired or wireless communication channel between the electronic apparatus 1 and the external electronic apparatus 2000 and the performance of communication via the established communication channel. The communication module 1730 may include one or both of a wireless communication module such as a cellular communication module, a short-range communication module, or a global navigation satellite system (GNSS) communication module, and a wired communication module such as a local area network (LAN) communication module or a power line communication module. The communication module 1730 may transmit and receive wireless signals over the Internet by using at least one of wireless LAN (WLAN), wireless-fidelity (Wi-Fi), Wi-Fi direct, or digital living network alliance (DLNA) technologies. Also, the communication module 1730 may support short-range communication by using at least one of Bluetooth™, radio frequency identification (RFID), infrared data association (IrDA), ultra-wideband (UWB), ZigBee, near-field communication (NFC), Wi-Fi, Wi-Fi direct, or wireless USB technologies. The various types of communication modules 1730 described above may be implemented as a single chip or as separate chips.

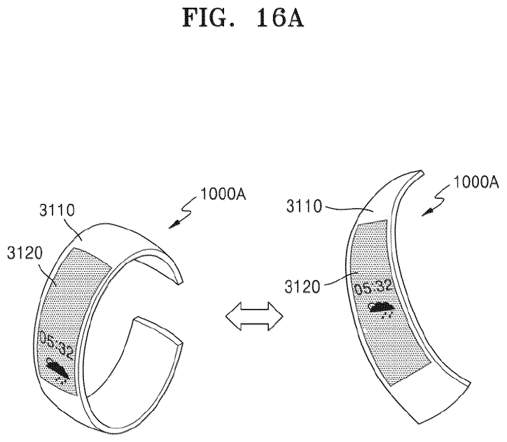

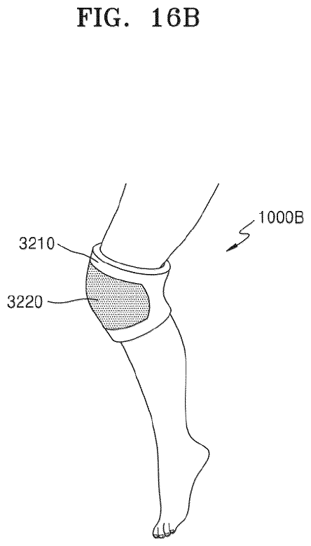

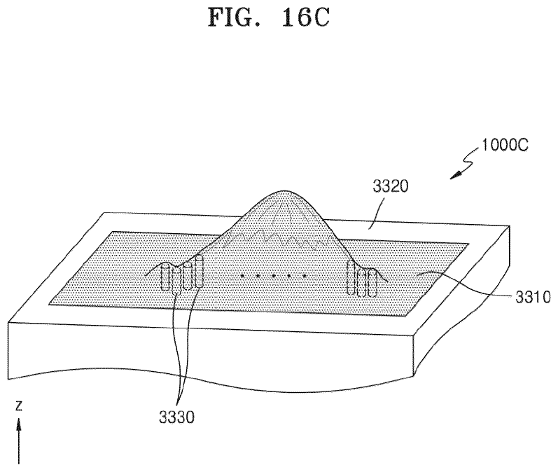

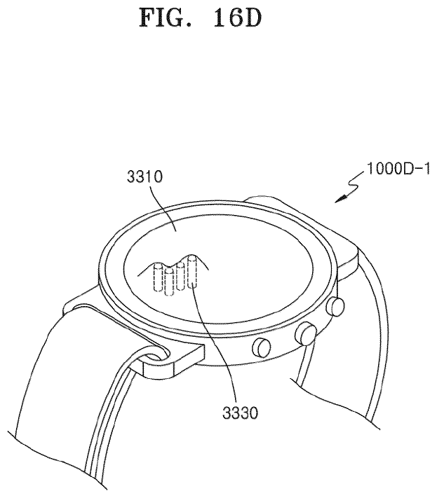

FIG. 16A-16D are respectively schematic perspective views showing embodiments of an electronic apparatus including a display apparatus, according to one or more embodiments.

Referring to FIG. 16A, the display apparatus according to one or more embodiments may be used in a wearable electronic apparatus 1000A that may be worn on a part of the body of a user. The wearable electronic apparatus 1000A may include a body 3110 and a display 3120 provided in the body 3110. The display apparatus according to one or more embodiments may be used as the display 3120 of the wearable electronic apparatus 1000A. As shown in FIG. 16A, the wearable electronic apparatus 1000A may be transformable. In one or more embodiments, the wearable electronic apparatus 1000A may be used as a smart watch or smartphone according to selection of the user.

FIG. 16B illustrates a medical electronic apparatus 1000B. In one or more embodiments, the medical electronic apparatus 1000B may include a body 3210 and a light-emitting portion 3220. The display apparatus according to one or more embodiments may be used as the light-emitting portion 3220 of the medical electronic apparatus 1000B. The light-emitting portion 3220 may emit light (e.g., infrared light, visible light, and/or the like) in a certain wavelength band to the body of a patient. In one or more embodiments, the body 3210 may include a stretchable fiber material, and the light-emitting portion 3220 may have a structure that may be worn on the body of a user.

FIG. 16C illustrates an educational electronic apparatus 1000C. In one or more embodiments, the educational electronic apparatus 1000C may include a display 3310 provided in a frame 3320. The display 3310 may use the display apparatus according to one or more embodiments. The display 3310 may provide images such as a sea with waves, a mountain covered in snow, or a volcano with flowing lava, and in this case, the display 3310 may be stretched in a height direction (e.g., a z-direction) to reflect the height of the waves, mountain, and/or volcano. In one or more embodiments, a portion of the display 3310 may show the movement of lava in three dimensions by sequentially changing the height in a direction in which the lava flows. The educational electronic apparatus 1000C may include a plurality of pins (or stroke portions) 3330 arranged on the rear surface of the display 3310 such that the display 3310 is stretched in the height direction. As the pins 3330 move in a third direction (e.g., the z-direction or a −z direction), images displayed on the display 3310 may be implemented to have a three-dimensional height. FIG. 16C illustrates the educational electronic apparatus 1000C, but the use thereof is not limited as long as certain image information is provided.

FIG. 16D illustrates that a display apparatus is used in a wearable electronic apparatus 1000D-1 such as a smart watch. In one or more embodiments, a display apparatus corresponding to a display 3310 of the wearable electronic apparatus 1000D-1 is three-dimensionally stretchable and thus may provide various types of haptic information to a user. In one or more embodiments, the wearable display apparatus 1000D-1 may provide haptic information such as Braille display for the visually impaired or tactile stimulation linked to an image, by using a plurality of pins (or stroke portions) 3330 arranged below the display 3310. The display apparatus forming the display 3310 is three-dimensionally stretchable and thus may provide the aforementioned haptic information to the user.

The embodiments described with reference to FIG. 16A-16D illustrate the electronic apparatuses 1000A, 1000B, 1000C, and 1000D-1 having a three-dimensionally transformable display, but the present disclosure is not limited thereto. As in embodiments to be described below, the display apparatus according to one or more embodiments may be used in an electronic apparatus in which an area (e.g., a screen) where images may be expressed is fixed.

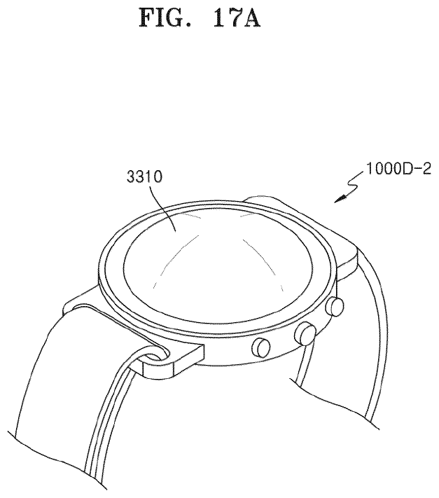

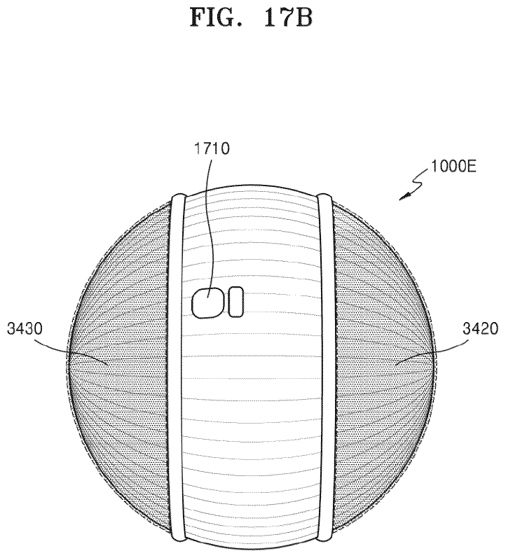

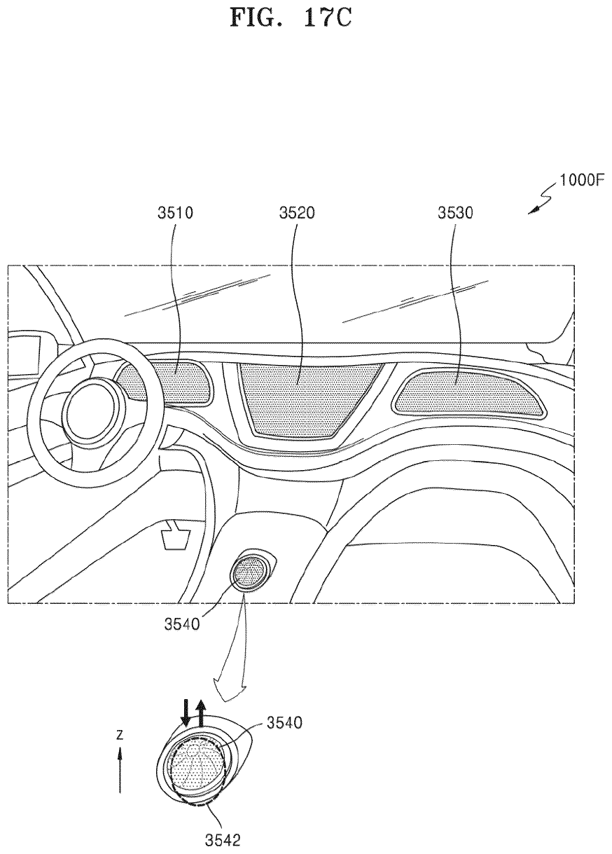

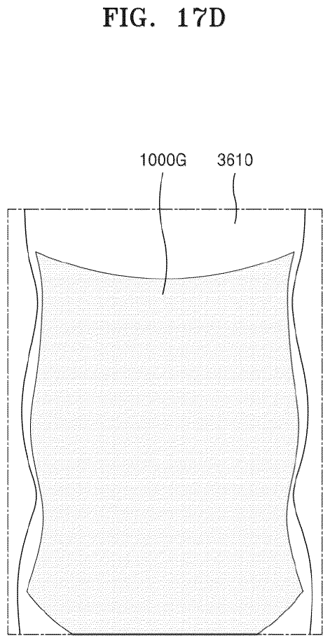

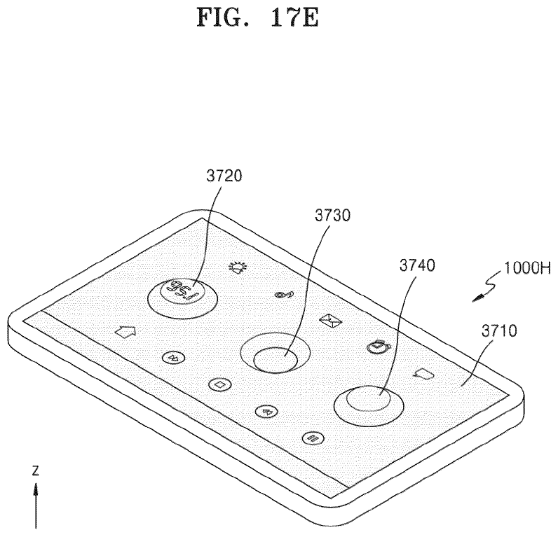

FIG. 17A-17E are respectively schematic perspective views of an electronic apparatus according to one or more embodiments.

FIG. 17A illustrates that a display apparatus is used in a wearable electronic apparatus 1000D-2 such as a smart watch. The wearable electronic apparatus 1000D-2 shown in FIG. 17A includes a display 3310, but the display 3310 may have a three-dimensional dome shape (or hemispherical shape). In a process of manufacturing the wearable electronic apparatus 1000D-2, a display apparatus may be assembled on a dome-shaped body frame, in which case the display apparatus is three-dimensionally stretchable and thus may be assembled in a stretched state according to the shape of the hemispherical body frame.

FIG. 17B illustrates that an electronic apparatus 1000E according to one or more embodiments includes a robot. The robot may recognize a movement or object by using the camera module 1710 and display a certain image to a user through displays 3420 and 3430. The display apparatuses according to one or more embodiments may be stretched in various directions as described above and thus may be assembled into a body frame having a hemispherical shape, and accordingly, the robot may include hemispherical displays 3420 and 3430.

FIG. 17C illustrates a vehicle display apparatus 1000F as an electronic apparatus according to one or more embodiments. The vehicle display apparatus 1000F may include a cluster 3510, a center information display (CID) 3520, and/or a passenger display (or co-driver display) 3530. The display apparatus according to one or more embodiments may be stretched in various directions and thus may be used in the cluster 3510, the CID 3520, and/or the co-driver display 3530 regardless of the shape of an internal frame of a vehicle.

FIG. 17C illustrates that the cluster 3510, the CID 3520, and/or the co-driver display 3530 are separated from each other, but the present disclosure is not limited thereto. In another embodiment, two or more selected from among the cluster 3510, the CID 3520, and the co-driver display 3530 may be integrally connected.

In one or more embodiments, the vehicle display apparatus 1000F may include a button 3540 that may express certain images. Referring to an enlarged diagram of FIG. 17C, the button 3540 having a hemispherical shape may include an object 3542 that provides the feeling of using a button while moving in a z-direction or a −z direction, and a display apparatus arranged over the object 3542. In one or more embodiments, when the object 3542 has a three-dimensionally round surface, the display apparatus may also have a three-dimensionally round surface.

FIG. 17D illustrates that an electronic apparatus according to one or more embodiments is an advertising or exhibition electronic apparatus 1000G. In some embodiments, the advertising or exhibition electronic apparatus 1000G may be installed on a fixed structure 3610 such as a wall or a pillar. When the structure 3610 includes an uneven surface as shown in FIG. 17D, the advertising or exhibition electronic apparatus 1000G may also be arranged along the uneven surface of the structure 3610. In one or more embodiments, the advertising or exhibition electronic apparatus 1000G may be installed on the structure 3610 by using a heat-shrink film and/or the like.

FIG. 17E illustrates that an electronic apparatus 1000H according to one or more embodiments is a controller. The controller may include an image-type button. For example, the controller may include first to third button areas 3720, 3730, and 3740 in which a portion of a display 3710 protrudes in the z-direction or protrudes in the −z direction (or is recessed in the z-direction). In one or more embodiments, the first and third button areas 3720 and 3740 may protrude in the z-direction, and the second button area 3730 may protrude in the −z direction (or be recessed in the z-direction).

The present disclosure has been described with reference to the one or more embodiments shown in the accompanying drawings, but may be considered in a descriptive sense only. Those of ordinary skill in the art will understand that various modifications and equivalent embodiments may be made therefrom. Therefore, the true technical scope of protection of the present disclosure may be defined by the technical spirit of the appended claims and their equivalents.

According to some embodiments, a display panel having high elasticity and a high yield due to a reduced defect rate in a manufacturing process, a process of manufacturing the display panel, and an electronic apparatus including the display panel may be provided. The effects, aspects, and features described above are merely examples, and the effects, aspects, and features of the present disclosure are not limited to those described above.

It should be understood that the embodiments described herein should be considered in a descriptive sense only and not for purposes of limitation. Descriptions of features or aspects within each of the embodiments should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a base layer including a first surface and a second surface opposite to the first surface;
a first pixel circuit layer on the first surface of the base layer and comprising insulating layers, a first line, and a first electrode pad;
a second pixel circuit layer on the first surface of the base layer, spaced from the first pixel circuit layer, and comprising insulating layers, a second line, and a second electrode pad;
a first light-emitting diode on the first pixel circuit layer and electrically connected to the first electrode pad;
a second light-emitting diode on the second pixel circuit layer and electrically connected to the second electrode pad; and
a connection line on the first surface of the base layer and electrically connecting the first line and the second line to each other,
wherein each of the connection line, the first electrode pad, and the second electrode pad has a lower surface and an upper surface, the lower surface facing the base layer, and the upper surface opposite the lower surface, and
wherein the upper surface of the connection line protrudes from the upper surface of the first electrode pad and the upper surface of the second electrode pad.

2. The display panel of claim 1, wherein, as the connection line is further away from the first light-emitting diode and the second light-emitting diode, the connection line becomes thicker in a thickness direction of the display panel.

3. The display panel of claim 1, wherein, in a plan view, as the connection line is further away from the first light-emitting diode and the second light-emitting diode, the connection line becomes thicker in a direction crossing an extension direction of the connection line.

4. The display panel of claim 1, wherein the base layer fills an opening defined by the first pixel circuit layer and the second pixel circuit layer.

5. The display panel of claim 1, wherein the connection line fills a portion of an opening defined by the first pixel circuit layer and the second pixel circuit layer.

6. The display panel of claim 5, wherein a side of the opening has a stepped shape.

7. The display panel of claim 1, wherein each of bonding layers is between the first light-emitting diode and the first electrode pad or between the second light-emitting diode and the second electrode pad.

8. The display panel of claim 1, wherein each of the first line and the second line comprises a first portion, a second portion, and a bridge line, the second portion being spaced from the first portion, and the bridge line connecting the first portion and the second portion to each other.

9. The display panel of claim 1, further comprising a cover layer on the first light-emitting diode, the second light-emitting diode, and the connection line,
wherein the base layer and the cover layer comprise an elastic body.

10. The display panel of claim 9, wherein the lower surface of the connection line is in contact with the base layer, and the upper surface of the connection line is in contact with the cover layer.

11. A method of manufacturing a display panel, the method comprising:
forming a pixel circuit layer on a first substrate, the pixel circuit layer comprising insulating layers, a first line, a second line, a first electrode pad electrically connected to the first line, and a second electrode pad electrically connected to the second line;
forming a bonding layer overlapping each of the first electrode pad and the second electrode pad;
forming a connection line that electrically connects the first line and the second line to each other;
attaching a first light-emitting diode to the first electrode pad and attaching a second light-emitting diode to the second electrode pad;
forming a cover layer on the first light-emitting diode, the second light-emitting diode, and the connection line;
separating the first substrate and the pixel circuit layer from each other;
forming an opening, a first pixel circuit layer, and a second pixel circuit layer by removing a portion of the pixel circuit layer, the first pixel circuit layer and the second pixel circuit layer being spaced from each other with the opening therebetween; and
forming a base layer supporting the first pixel circuit layer and the second pixel circuit layer.

12. The method of claim 11, wherein the attaching of the first light-emitting diode to the first electrode pad and attaching of the second light-emitting diode to the second electrode pad comprises:
preparing a second substrate, a resin layer, and the first light-emitting diode and the second light-emitting diode, the second substrate including a first surface facing the first substrate and a second surface opposite the first surface, the resin layer being on the first surface of the second substrate, and the first light-emitting diode and the second light-emitting diode being attached to the resin layer; and
attaching the first light-emitting diode to the first electrode pad and attaching the second light-emitting diode to the second electrode pad by pressing the second substrate.

13. The method of claim 12, wherein, when the second substrate is pressed, the connection line is in contact with the resin layer.

14. The method of claim 11, wherein, as the connection line is further away from the first light-emitting diode and the second light-emitting diode, the connection line is thicker in a thickness direction of the display panel.

15. The method of claim 11, wherein, in a plan view, as the connection line is further away from the first light-emitting diode and the second light-emitting diode, the connection line is thicker in a direction crossing an extension direction of the connection line.

16. A method of manufacturing a display panel, the method comprising:
forming a pixel circuit layer on a first substrate, the pixel circuit layer comprising insulating layers, a first line, a second line, a first electrode pad electrically connected to the first line, and a second electrode pad electrically connected to the second line;
forming an opening, a first pixel circuit layer, and a second pixel circuit layer by removing a portion of the pixel circuit layer, the first pixel circuit layer and the second pixel circuit layer being spaced from each other with the opening therebetween;
patterning a bonding layer to overlap each of the first electrode pad and the second electrode pad;
forming a connection line that electrically connects the first line and the second line to each other;
attaching a first light-emitting diode to the first electrode pad and attaching a second light-emitting diode to the second electrode pad;
forming a cover layer on the first light-emitting diode, the second light-emitting diode, and the connection line;
separating the first substrate, the first pixel circuit layer, the second pixel circuit layer, and the cover layer from each other; and
forming a base layer supporting the first pixel circuit layer and the second pixel circuit layer.

17. The method of claim 16, wherein the attaching of the first light-emitting diode to the first electrode pad and attaching of the second light-emitting diode to the second electrode pad comprises:
preparing a second substrate, a resin layer, and the first light-emitting diode and the second light-emitting diode, the second substrate including a first surface facing the first substrate and a second surface opposite the first surface, the resin layer being on the first surface of the second substrate, and the first light-emitting diode and the second light-emitting diode being attached to the resin layer; and
attaching the first light-emitting diode to the first electrode pad and attaching the second light-emitting diode to the second electrode pad by pressing the second substrate.

18. The method of claim 17, wherein, when the second substrate is pressed, the connection line is in contact with the resin layer.

19. The method of claim 16, wherein the connection line fills a portion of the opening.

20. The method of claim 16, wherein, as the connection line is further away from the first light-emitting diode and the second light-emitting diode, the connection line is thicker in a thickness direction of the display panel.
